(19) United States
(12) Patent Application Publication
(10) Pub. No.: US 2024/0179914 A1
(43) Pub. Date: May 30, 2024

(54) SEMICONDUCTOR DEVICE

(71) Applicant: SAMSUNG ELECTRONICS CO., LTD., SUWON-SI (KR)

(72) Inventors: Chulmin Choi, Suwon-si (KR); Sunil Shim, Suwon-si (KR); Joohyun Lim, Suwon-si (KR)

(21) Appl. No.: 18/510,209

(22) Filed: Nov. 15, 2023

(30) Foreign Application Priority Data
Nov. 24, 2022 (KR) 10-2022-0158864

(51) Int. Cl. H10B 43/27; H10B 43/10; H10B 43/35; H10B 43/40

(52) U.S. Cl. CPC H10B 43/27; H10B 43/10; H10B 43/35; H10B 43/40

(57) ABSTRACT

A semiconductor device includes a gate electrode structure including first to fourth gate electrodes, a first memory channel structure extending through the first to third gate electrodes, a second memory channel structure contacting an upper surface of the first memory channel structure and extending through the fourth gate electrode, and a first contact plug including a lower portion extending partially through the gate electrode structure and an upper portion on and contacting an upper surface of the lower portion. The lower portion of the first contact plug has a varying width, and the upper portion of the first contact plug has a width gradually increasing from a bottom toward a top thereof. The lower portion of the first contact plug extends through the first, second and third gate electrodes, and is electrically insulated from the first and second gate electrodes, and is electrically connected to the third gate electrode.

### CROSS-REFERENCE TO RELATED APPLICATIONS

This application claims priority under 35 USC § 119 to Korean Patent Application No. 10-2022-0158864, filed on Nov. 24, 2022 in the Korean Intellectual Property Office (KIPO), the contents of which are herein incorporated by reference in their entirety.

### TECHNICAL FIELD

The inventive concepts relate to a semiconductor device, and more particularly to a multi-layer memory device.

### DISCUSSION OF RELATED ART

In an electronic system requiring data storage, a high capacity semiconductor device that may store high capacity data can be used. Thus, a method of increasing the data storage capacity of the semiconductor device has been studied. For example, a semiconductor device including memory cells that may be 3-dimensionally stacked has been suggested.

In a method of manufacturing a semiconductor device, contact plugs for transferring electric signals to gate electrodes may be efficiently formed.

### SUMMARY

Example embodiments provide a method of manufacturing a semiconductor device having improved characteristics.

According to an aspect of the inventive concept, there is provided a semiconductor device. The semiconductor device may include a gate electrode structure including first, second, third and fourth gate electrodes spaced apart from each other on a substrate in a first direction substantially perpendicular to an upper surface of the substrate, each of which may extend in a second direction substantially parallel to the upper surface of the substrate, a first memory channel structure extending through the first, second and third gate electrodes on the substrate, a second memory channel structure contacting an upper surface of the first memory channel structure and extending through the fourth gate electrodes, and a first contact plug including a lower portion extending partially through the gate electrode structure and an upper portion on and contacting an upper surface of the lower portion. The lower portion of the first contact plug may extend through the first, second and third gate electrodes, and may be electrically insulated from the first and second gate electrodes, but may be electrically connected to the third gate electrode.

According to an aspect of the inventive concept, there is provided a semiconductor device. The semiconductor device may include a lower circuit pattern on a substrate, an upper wiring over the lower circuit pattern, a gate electrode structure including first, second, third and fourth gate electrodes spaced apart from each other over the upper wiring in a first direction substantially perpendicular to an upper surface of the substrate, each of which may extend in a second direction substantially parallel to the upper surface of the substrate, a first memory channel structure extending through the first gate electrode, a second memory channel structure contacting an upper surface of the first memory channel structure and extending through the second, third and fourth gate electrodes, a first contact plug including an upper portion and a lower portion, wherein the lower portion is beneath and contacting a lower surface of the upper portion, and wherein the upper portion extends partially through the gate electrode structure, and a second contact plug including an upper portion extending partially through the gate electrode structure and a lower portion, wherein the lower portion is beneath and contacting a lower surface of the upper portion. A length in the second direction of the fourth gate electrode may be greater than a length in the second direction of the third gate electrode, the length in the second direction of the third gate electrode may be greater than a length in the second direction of the second gate electrode, and the length in the second direction of the second gate electrode may be greater than a length in the second direction of the first gate electrode. The upper portion of the first contact plug may extend through the second, third and fourth gate electrodes, and may not be electrically connected to the third and fourth gate electrodes, but may be electrically connected to the second gate electrode. The upper portion of the second contact plug may extend through the third and fourth gate electrodes, and may not be electrically connected to the fourth gate electrode, but may be electrically connected to the third gate electrode.

According to an aspect of the inventive concept, there is provided a semiconductor device. The semiconductor device may include a lower circuit pattern on a substrate including first and second regions, a common source plate (CSP) on the lower circuit pattern, a gate electrode structure including first, second, third, fourth and fifth gate electrodes spaced apart from each other on the CSP in a first direction substantially perpendicular to an upper surface of the substrate, each of which may extend in a second direction substantially parallel to the upper surface of the substrate, a first memory channel structure extending through the first to fourth gate electrodes on the CSP on the first region of the substrate, a second memory channel structure contacting an upper surface of the first memory channel structure and extending through the fifth gate electrodes, a support structure on the CSP on the second region of the substrate and partially extending through the gate electrode structure, a first contact plug including a lower portion extending partially through the gate electrode structure on the second region of the substrate and an upper portion on and contacting an upper surface of the lower portion, and a second contact plug including a lower portion extending partially through the gate electrode structure on the second region of the substrate, and an upper portion on and contacting an upper surface of the lower portion. The lower portion of each of the first and second contact plugs may have a width varying in the first direction, and the upper portion of each of the first and second contact plugs may have a width gradually increasing from a bottom toward a top thereof. Each of the first and second contact plugs may contact one of the first to fifth gate electrodes. Upper surfaces of the first memory channel structure, the support structure and the lower portions of the first and second contact plugs may be substantially coplanar with each other.

In the semiconductor device in accordance with example embodiments, the contact plugs electrically connected to the ground selection line (GSL), the gate induced drain leakage (GIDL) gate electrode and the word line, respectively, may be formed by the same process, which may simplify the manufacture method and reduce the cost.

### BRIEF DESCRIPTION OF THE DRAWINGS

FIGS. 1 to 7 are a plan view and cross-sectional views illustrating a semiconductor device in accordance with example embodiments.

FIGS. 8 to 55 are plan views and cross-sectional views illustrating a method of manufacturing a semiconductor device in accordance with example embodiments.

FIG. 56 is a cross-sectional view illustrating a semiconductor device in accordance with example embodiments.

FIG. 57 is a cross-sectional view illustrating a semiconductor device in accordance with example embodiments.

FIG. 58 is a cross-sectional view illustrating a semiconductor device in accordance with example embodiments.

### DETAILED DESCRIPTION

Hereinafter, a semiconductor device and a method for manufacturing the same in accordance with example embodiments will be described in detail with reference to the accompanying drawings. It will be understood that, although the terms “first,” “second,” and/or “third” may be used herein to describe various elements, these elements should not be limited by these terms. These terms are only used to distinguish one element from another element.

In the specification (and not necessarily in the claims), a vertical direction substantially perpendicular to an upper surface of a substrate may be referred to as a first direction D1, and two directions crossing each other among horizontal directions substantially parallel to the upper surface of the substrate may be referred to as second and third directions D2 and D3, respectively. In example embodiments, the second and third directions may be substantially perpendicular to each other.

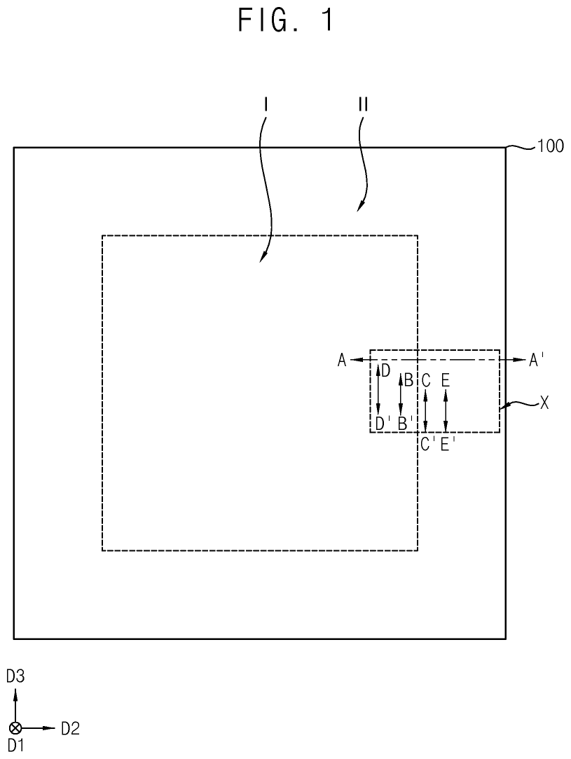

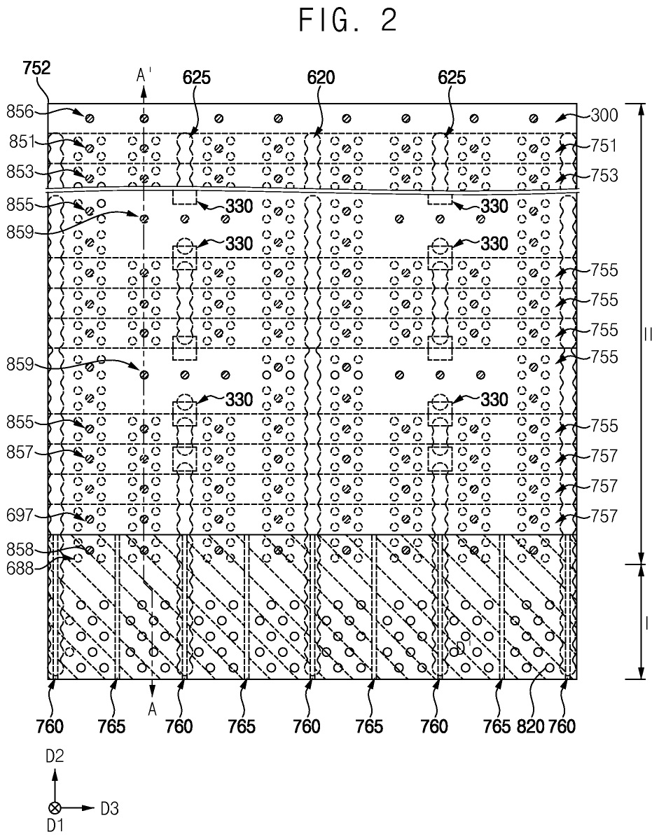

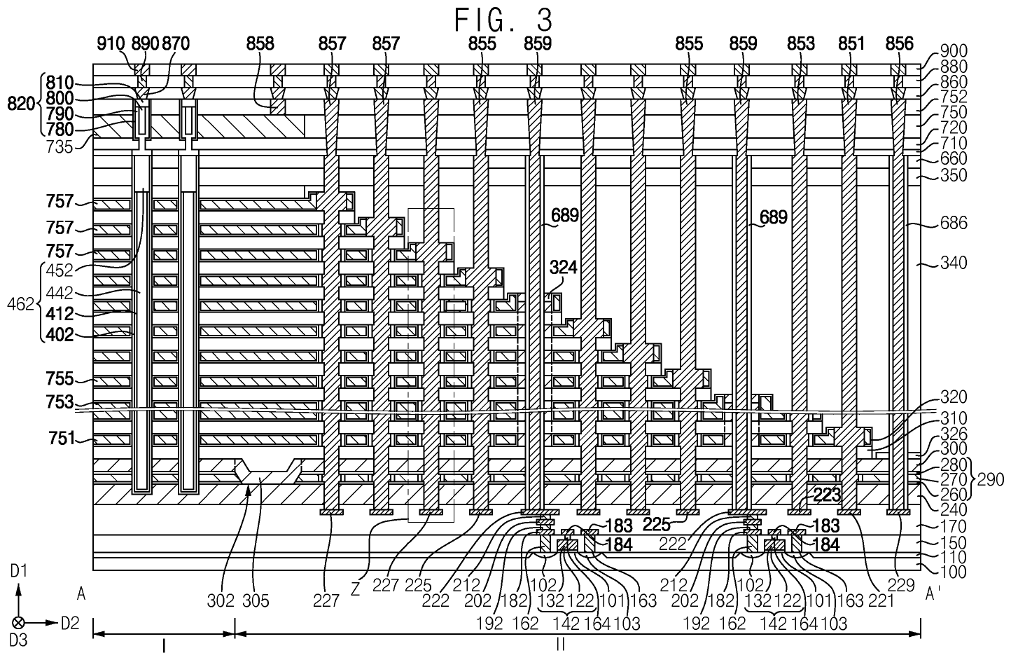

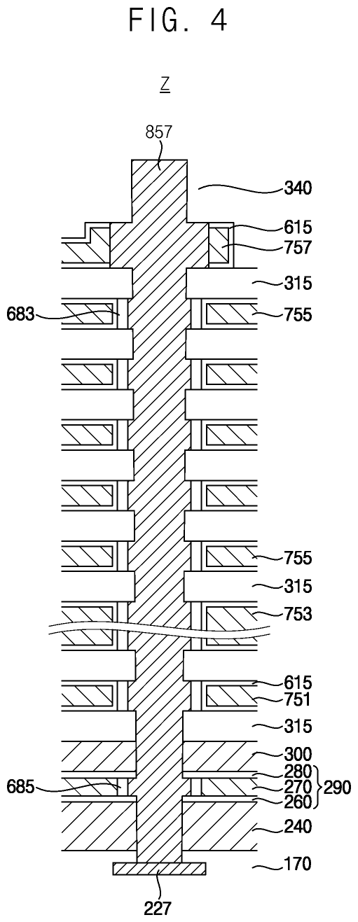

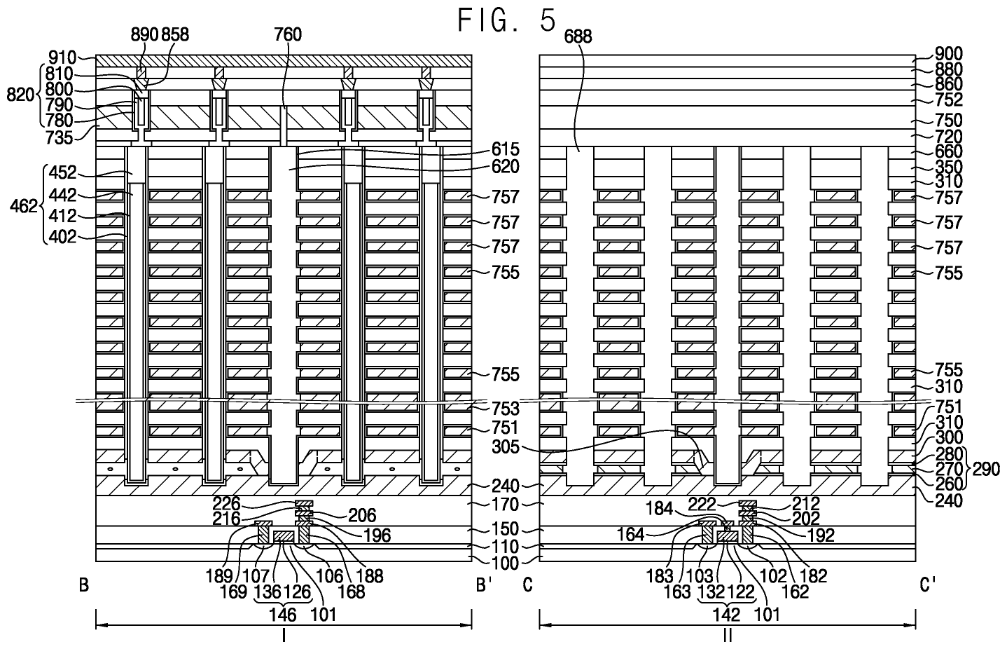

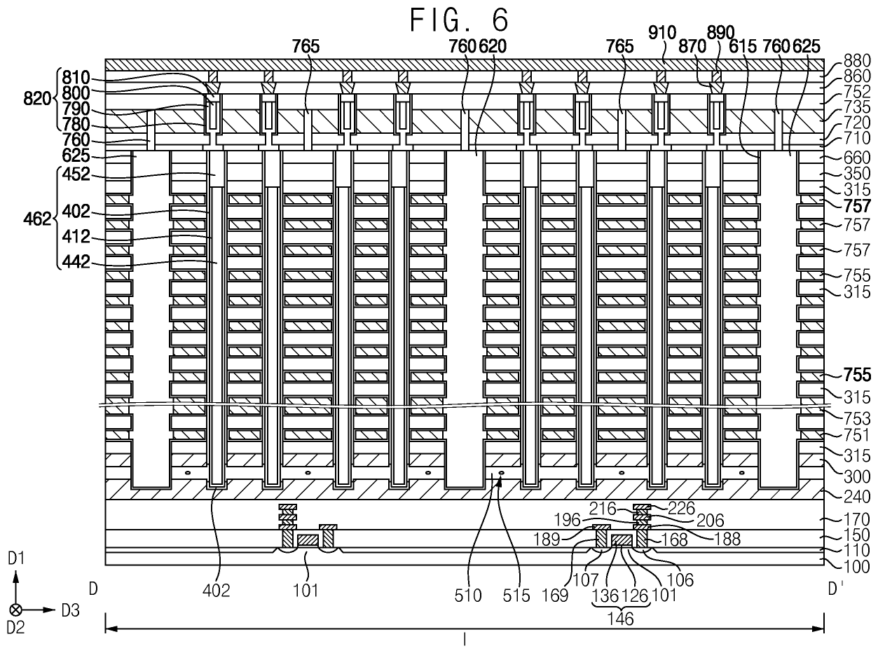

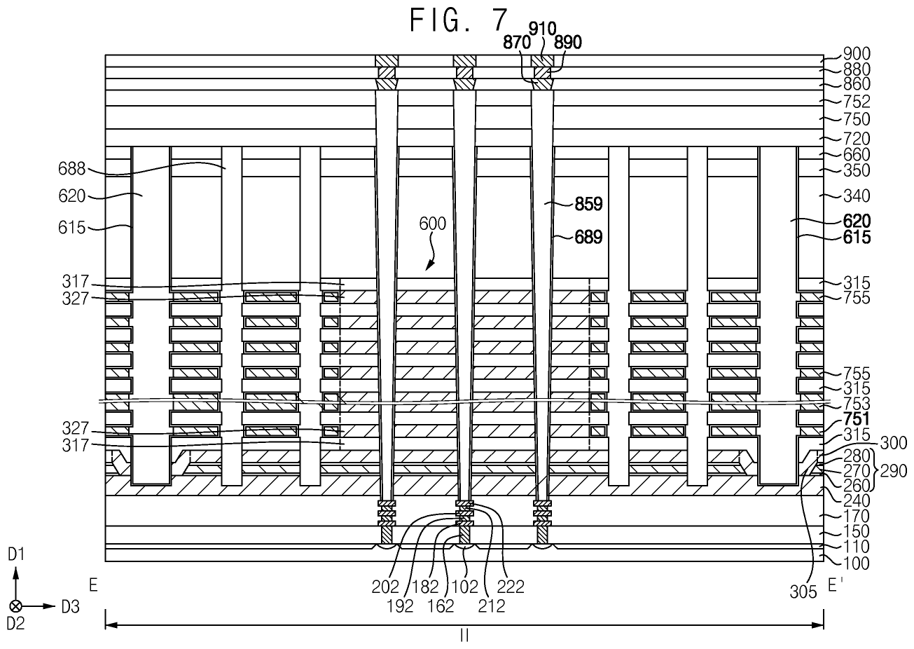

FIGS. 1 to 7 are a plan view and cross-sectional views illustrating a semiconductor device in accordance with example embodiments. Particularly, FIGS. 1 and 2 are the plan view, FIGS. 3 and 4 are cross-sectional views taken along line A-A′ of FIG. 2, FIG. 5 includes cross-sectional views taken along lines B-B′ and C-C′, respectively, of FIG. 2, FIG. 6 is a cross-sectional view taken along line D-D′ of FIG. 2, and FIG. 7 is a cross-sectional view taken along line E-E′ of FIG. 2. FIGS. 2 to 7 are drawings about region X in FIG. 1, and FIG. 4 is an enlarged cross-sectional view of region Z in FIG. 3.

FIG. 2 does not show some elements shown in other figures, e.g., upper wirings, upper vias and upper contact plugs in order to reduce the complexity of the drawing.

Referring to FIGS. 1 to 7, the semiconductor device may include a lower circuit pattern, a common source plate (CSP), a gate electrode structure, first to fifth division patterns 330, 620, 625, 760 and 765, a support structure 688, an insulation pattern structure 600, first memory channel structures 462 and second memory channel structures 820, first to eighth upper contact plugs 851, 853, 855, 857, 856, 859, 858 and 870, an upper via 890 and an upper wiring 910 on a substrate 100.

Additionally, the semiconductor device may include a support layer 300, a support pattern 305, a sacrificial layer structure 290, a channel connection pattern 510 (see e.g., FIG. 6), a second blocking pattern 615, second and third insulation pads 324 and 326, first to fifth insulation patterns 315, 683, 685, 686, and 689, first to fifth insulating interlayers 150, 170, 350 and 660, an etch stop layer 720, and seventh to twelfth insulating interlayers 710, 750, 752, 860, 880, and 900.

The substrate 100 may include a semiconductor material, e.g., silicon, germanium, silicon-germanium, etc., or a III-V group compound semiconductor, e.g., GaP, GaAs, GaSb, etc. In example embodiments, the substrate 100 may be a silicon-on-insulator (SOI) substrate or a germanium-on-insulator (GOI) substrate.

In example embodiments, the substrate 100 may include a first region I and a second region II surrounding the first region I. In example embodiments, the first region I may be a cell array region, the second region II may be a pad region or an extension region, and the first and second regions I and II may collectively form a cell region.

In example embodiments, the memory cells, each of which may include a gate electrode, a channel and a charge strontium structure, may be formed on the first region, I, of the substrate 100, and upper contact plugs for transferring electric signals to the memory cells and pads of the gate electrodes contacting the upper contact plugs may be formed on the second region, II, of the substrate 100. FIG. 1 shows that the second region II can entirely surround the first region I, however, the inventive concept may not be limited thereto, and for example, the second region II may be formed at each of opposite sides in the second direction D2 of the first region I.

In example embodiments, a third region surrounding the second region II may be further formed, and an upper circuit pattern for applying the electric signals to the memory cells through the upper contact plugs may be formed on the third region of the substrate 100.

In example embodiments, the substrate 100 may include a field region on which an isolation pattern 110 is formed, and an active region 101 on which no isolation pattern 110 is formed. The isolation pattern 110 may include an oxide, e.g., silicon oxide. The isolation pattern 110 can electrically separate the active regions 101.

In example embodiments, the semiconductor device may have a cell over periphery (COP) structure, where the lower circuit pattern may be formed on the substrate 100, and the memory cells, the upper contact plugs and the upper circuit pattern may be formed on the lower circuit pattern. The lower circuit pattern may include, e.g., transistors, lower contact plugs, lower wirings, lower vias, etc.

For example, as shown for example in FIG. 5, first and second transistors may be formed on the second and first regions II and I, respectively, of the substrate 100. The first transistor may include a first lower gate structure 142 on the substrate 100, and first and second impurity regions 102 and 103 on upper portions, respectively, of the active region 101 adjacent to the first lower gate structure 142 and serving as source/drains. The first and second impurity regions 102 and 103 can be between portions of the isolation pattern 110. The second transistor may include a second lower gate structure 146 on the substrate 100, and third and fourth impurity regions 106 and 107 on upper portions, respectively, of the active region 101 adjacent to the second lower gate structure 146 and serving as source/drains. The third and fourth impurity regions 106 and 107 can be between portions of the isolation pattern 110.

In example embodiments, the first lower gate structure 142 may include a first lower gate insulation pattern 122 and a first lower gate electrode 132 stacked on the substrate 100, and the second lower gate structure 146 may include a second gate insulation pattern 126 and a second lower gate electrode 136 stacked on the substrate 100.

In example embodiments, the first insulating interlayer 150 may cover the first and second transistors on the substrate 100, the first, second, fourth and fifth lower contact plugs 162, 163, 168 and 169 may extend through the first insulating interlayer 150 to contact the first to fourth impurity regions 102, 103, 106 and 107, respectively, and the third lower contact plug 164 may extend through the first insulating interlayer 150 to contact the first lower gate electrode 132. A sixth lower contact plug may extend through the first insulating interlayer 150 to contact the second lower gate electrode 136.

In example embodiments, the first to fifth lower wirings 182, 183, 184, 188 and 189 may be formed on the first insulating interlayer 150 to contact the first to fifth lower contact plugs 162, 163, 164, 168 and 169, respectively. The first lower via 192, the sixth lower wiring 202, the third lower via 212 and the eighth lower wiring 222 may be sequentially stacked on the first lower wiring 182, and the second lower via 196, the seventh lower wiring 206, the fourth lower via 216 and the ninth lower wiring 226 may be sequentially stacked on the fourth lower wiring 188.

In example embodiments, the tenth to fourteenth lower wirings 221, 223, 225, 227 and 229 may be further formed at the same levels as the eighth and ninth lower wirings 222 and 226, which may be electrically connected to other transistors on the substrate 100.

In example embodiments, the second insulating interlayer 170 may be formed on the first insulating interlayer 150, and may cover the first to fourteenth lower wirings 182, 183, 184, 188, 189, 202, 206, 222, 226, 221, 223, 225, 227 and 229 and the first to fourth lower vias 192, 196, 212 and 216.

In example embodiments, the CSP 240 may be formed on the second insulating interlayer 170. The CSP 240 may include, e.g., polysilicon doped with n-type impurities. Alternatively, the CSP 240 may have a metal silicide layer and a doped polysilicon layer sequentially stacked. The metal silicide layer may include, e.g., tungsten silicide.

In example embodiments, the sacrificial layer structure 290, the channel connection pattern 510 (see e.g., FIG. 6), the support layer 300 and the support pattern 305 (see e.g., FIG. 5) may be formed on the CSP 240.

In example embodiments, the channel connection pattern 510 may be formed on the first region I of the substrate 100, and the sacrificial layer structure 290 may be formed on the second region II of the substrate 100. The channel connection pattern 510 may include an air gap 515.

In example embodiments, the support layer 300 may be formed on the channel connection pattern 510 and the sacrificial layer structure 290. A portion of the support layer 300 may be formed in a first opening 302 exposing an upper surface of the CSP 240, which may be referred to as the support pattern 305.

In example embodiments, the support pattern 305 may be formed in various layouts in a plan view. For example, a plurality of support patterns 305 may be spaced apart from each other in the second and third directions D2 and D3 on the first region I of the substrate 100, the support pattern 305 may extend in the third direction D3 on a portion of the second region II adjacent to the first region I of the substrate 100, and a plurality of support patterns 305, each of which may extend in the second direction D2, may be spaced apart from each other in the third direction D3. FIG. 3 shows the support pattern 305 extending in the third direction D3 on the portion of the second region II adjacent to the first region I of the substrate 100.

In example embodiments, the channel connection pattern 510 may include polysilicon doped with n-type impurities or undoped polysilicon. The sacrificial layer structure 290 may include first, second and third sacrificial layers 260, 270 and 280 sequentially stacked in the first direction D1. The first and third sacrificial layers 260 and 280 may include an oxide, e.g., silicon oxide, and the second sacrificial layer 270 may include a nitride, e.g., silicon nitride. The support layer 300 and the support pattern 305 may include a material having an etching selectivity with respect to the first to third sacrificial layers 260, 270 and 280, e.g., polysilicon doped with n-type impurities.

In example embodiments, the gate electrode structure may include gate electrodes at a plurality of levels, respectively, that are spaced apart from each other in the first direction D1 on the support layer 300 and the support pattern 305. Each of the gate electrodes may extend in the second direction D2. A gate electrode structure can include first, second, third and fourth gate electrodes spaced apart from each other on a substrate in a first direction substantially perpendicular to an upper surface of the substrate 100, where each of the first, second, third and fourth gate electrodes can extend in a second direction substantially parallel to the upper surface of the substrate 100.

In example embodiments, the gate electrode structure may include first, second, third, fourth and fifth gate electrodes 751, 753, 755, 757 and 735 sequentially stacked in the first direction D1. Each of the first, second, fourth and fifth gate electrodes 751, 753, 757 and 735 may be disposed at one or a plurality of levels, and the third gate electrodes 755 may be disposed at a plurality of levels, respectively. FIGS. 3 to 7 shows that the first, second and fifth gate electrodes 751, 753 and 735 are disposed at one level and the fourth gate electrodes 757 are disposed at three levels, respectively, however, the inventive concept may not be limited thereto.

In example embodiments, the first gate electrode 751 may serve as a ground selection line (GSL), the third gate electrode 755 may serve as a word line, and the fifth gate electrode 735 may serve as a string selection line (SSL). Each of the second and fourth gate electrodes 753 and 757 may serve as a gate induced drain leakage (GIDL) gate electrode, which may erase data stored in the first memory channel structure 462 using a GIDL phenomenon. Alternatively, the first gate electrode may serve as a GSL, the second gate electrode may serve as a word line, the third gate electrode can be a GIDL electrode, and the fourth gate electrode may serve as an SSL. Alternatively, the first gate electrode may serve as an SSL, the second gate electrode can be a GIDL electrode, the third gate electrode may serve as a word line, and the fourth gate electrode may serve as a GSL.

In example embodiments, the first gate electrode may be formed at a lowermost level, and may serve as a ground selection line (GSL). The second gate electrode 753 may be formed at one or a plurality of levels over the first gate electrode 751, and may serve as a GIDL gate electrode. The third gate electrodes 755 may be formed at a plurality of levels, respectively, over the second gate electrode 753, and may serve as word lines, respectively. The fourth gate electrode 757 may be formed at one or a plurality of levels over the third gate electrode 755, and may serve as the GIDL gate. In example embodiments, the first gate electrode may be formed at a lowermost level, and may serve as a ground selection line (GSL). The second gate electrode 753 may be formed at one or a plurality of levels over the first gate electrode 751, and may serve as a GIDL gate electrode. The third gate electrodes 755 may be formed at a plurality of levels, respectively, over the second gate electrode 753, and may serve as word lines, respectively. The fourth gate electrode 757 may be formed at one or a plurality of levels over the third gate electrode 755, and may serve as the GIDL gate electrode.

Each of the first to fourth gate electrodes 751, 753, 755 and 757 may include a gate conductive pattern and a gate barrier pattern covering a surface of the gate conductive pattern. The gate conductive pattern may include a metal having a low resistance, e.g., tungsten, titanium, tantalum, platinum, etc., and the gate barrier pattern may include a metal nitride, e.g., titanium nitride, tantalum nitride, etc. In example embodiments, the fifth gate electrode 735 may include, e.g., polysilicon doped with n-type impurities.

In example embodiments, the first insulation pattern 315 may be disposed between neighboring ones of the first to fourth gate electrodes 751, 753, 755 and 757, on an upper surface of an uppermost one of the fourth gate electrodes 757, and between the first gate electrode 751 and the support layer 300 or the support pattern 305 (see e.g., FIG. 4). The first insulation pattern 315 may include an oxide, e.g., silicon oxide.

In example embodiments, the gate electrode structure may have a staircase shape in which lengths in the second direction D2 decrease from a lowermost level toward an uppermost level (see e.g., FIG. 3), and thus may include steps arranged in the second direction D2 on the second region II of the substrate 100. Additionally, the gate electrode structure may further include steps arranged in the third direction D3 on the second region II of the substrate 100. As illustrated in FIG. 2, the dashed lines separating the first to fourth gate electrodes 751, 753, 755 and 757 can indicate the step edges formed along the second direction D2 on the second region II.

Hereinafter, a portion of the gate electrode that may correspond to the step of the gate electrode structure, where an end portion of the gate electrode that is not overlapped in the first direction D1 by upper gate electrodes may be referred to as a pad. Thus, the pads of the gate electrodes may be disposed on the second region II of the substrate 100. In example embodiments, the pad of each of the first to fourth gate electrodes 751, 753, 755 and 757 may have a thickness greater than thicknesses of other portions thereof. A top surface of each pad of the first to fourth gate electrodes 751, 753, 755 and 757 can be above the top surface of the corresponding gate electrode in the region of overlap, where the top surface of the pad can be between a top and bottom surface of the overlying first insulation pattern 315.

In example embodiments, the gate electrode structure may include first pads having relatively large lengths in the second direction D2 and second pads having relatively small lengths in the second direction D2, and the numbers of the first and second pads are not limited.

In example embodiments, a plurality of gate electrode structures may be spaced apart from each other in the third direction D3. The second division pattern 620 may be disposed and extend in the second direction D2 between neighboring ones of the plurality of gate electrode structures in the third direction D3 on the CSP 240.

In example embodiments, the third division pattern 625 may extend in the second direction D2 through the first to fourth gate electrodes 751, 753, 755 and 757 included in each of the gate electrode structures on the first region I and a portion of the second region II adjacent to the first region I of the substrate 100. The third division pattern 625, unlike the second division pattern 620, may not continuously extend to an end portion of the second region II of the substrate 100, but a plurality of third division patterns 625 may be spaced apart from each other in the second direction D2 on the second region II of the substrate 100. The third division patterns 625 can be an interrupted patterns with segments spaced apart along plateaus of the gate electrode structure.

In example embodiments, upper surfaces of the second and third division patterns 620 and 625 may be substantially coplanar with upper surfaces of the fifth insulating interlayer 660, the first memory channel structure 462 and the support structure 688.

In example embodiments, the first division pattern 330 may be formed on the second region II of the substrate 100, and may extend through the first gate electrode 751. In example embodiments, a plurality of first division patterns 330 may be spaced apart from each other in the second and third directions D2 and D3. The first division pattern 330 may contact an end portion in the second direction D2 of the third division pattern 625, and may overlap an end portion in the second direction D2 of the insulation pattern structure 600 in the first direction D1.

Each of the fourth and fifth division patterns 760 and 765 may extend through the seventh insulating interlayer 710, the etch stop layer 720, and the fifth gate electrode 735 in the second direction D2 on the first region I and a portion of the second region II adjacent thereto (see e.g., FIG. 6). In example embodiments, a plurality of fourth division patterns 760 may be spaced apart from each other in the third direction D3, and may contact upper surfaces of the second and third division patterns 620 and 625, where the lower surface of the fourth division patterns 760 and the upper surfaces of the second and third division patterns 620 and 625 can be coplanar with the upper surface of the fifth insulating interlayer 660. The fourth division patterns 760 may have a narrower width than the underlying second and third division patterns 620 and 625. The fifth division pattern 765 may be formed between ones of the fourth division patterns 760 neighboring in the third direction D3, and may contact an upper surface of the fifth insulating interlayer 660.

In example embodiments, the first to fifth division patterns 330, 620, 625, 760 and 765 may include an oxide, e.g., silicon oxide, where the first to fifth division patterns 330, 620, 625, 760 and 765 can be electrically insulating.

In example embodiments, a memory block may be formed at a region defined by ones of the second division patterns 620 neighboring in the third direction D3, and may include the gate electrode structure and the first and second memory channel structures 462 and 820. In example embodiments, a plurality of memory blocks may be arranged in the third direction D3.

In an example embodiment, each of the memory blocks may include two first gate electrodes 751 divided by the first division pattern 330, one second gate electrode 753, one third gate electrode 755, one fourth gate electrode 757, and four fifth gate electrodes 735 divided by the third to fifth division patterns 625, 760 and 765 at each level, however, the inventive concept may not be limited thereto. For example, each of the memory blocks may include two first gate electrodes 751 divided by the first division pattern 330, one second gate electrode 753, one third gate electrode 755, one fourth gate electrode 757, and six fifth gate electrodes 735 divided by the third to fifth division patterns 625, 760 and 765 at each level.

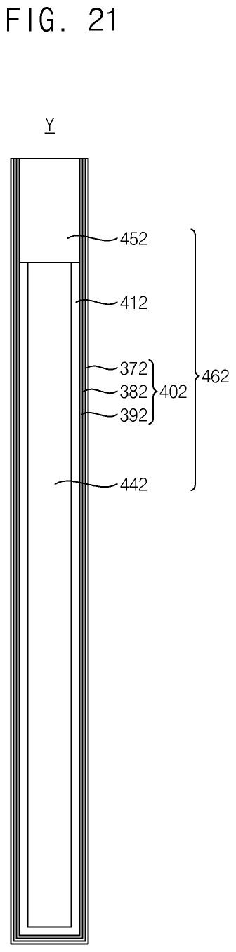

Referring to FIGS. 1 to 7 together with FIG. 21, the first memory channel structure 462 may be formed on the first region I of the substrate 100, and may contact an upper surface of the CSP 240. The first memory channel structure 462 may extend through the channel connection pattern 510, the first to fourth gate electrodes 751, 753, 755 and 757, the first insulation pattern 315, and the third and fourth insulating interlayers 340 and 350.

In example embodiments, the first memory channel structure 462 may include a first filling pattern 442 having a shape of a pillar extending in the first direction D1, a first channel 412 on a sidewall of the first filling pattern 442 and having a shape of a cup, a first capping pattern 452 contacting upper surfaces of the first filling pattern 442 and the first channel 412, and a first charge storage structure 402 on an outer sidewall of the first channel 412 and a sidewall of the first capping pattern 452.

In example embodiments, the first charge storage structure 402 may include a first tunnel insulation pattern 392, a first charge storage pattern 382 and a first blocking pattern 372 sequentially stacked on the outer sidewall of the first channel 412 in the horizontal direction (see e.g., FIG. 21).

In example embodiments, a plurality of first memory channel structures 462 may be spaced apart from each other in the second and third directions D2 and D3 on the first region I of the substrate 100 to form a first memory channel structure array, and a plurality of first memory channel structures 462 included in the first memory channel structure array may be electrically connected to each other by the channel connection pattern 510 (see e.g., FIG. 6). The first charge storage structure 402 may not be formed on a portion of the outer sidewall of two or more of the first channels 412, where the channel connection pattern 510 may contact the portion of the outer sidewall of the first channels 412, so that two or more the first channels 412 may be electrically connected to each other.

The support structure 688 may be formed on the second region II of the substrate 100, and may contact the upper surface of the CSP 240 (see e.g., FIG. 5). The support structure 688 may extend through the sacrificial layer structure 290, the first to fourth gate electrodes 751, 753, 755 and 757, the first insulation pattern 315, and the third and fourth insulating interlayers 340 and 350. In example embodiments, the support structure 688 may have a shape of a pillar extending in the first direction D1, and a plurality of protrusion portions, which may protrude in the horizontal direction, and may be spaced apart from each other in the first direction D1 on a sidewall of the pillar. The support structure 688 may include protrusion portions on portions of a sidewall extending laterally away from a continuous central portion, respectively, which face the first to fourth gate electrodes 751, 753, 755 and 757, respectively. The support structure 688 may include an oxide, e.g., silicon oxide.

In example embodiments, the support structure 688 may be spaced apart from each other in the second and third directions D2 and D3 on the second region II of the substrate 100.

In example embodiments, the second memory channel structure 820 may include a second filling pattern 800, a second channel 790, a second charge storage structure 780, and a second capping pattern 810. In example embodiments, the second memory channel structure 820 may extend through the seventh insulating interlayer 710, the etch stop layer 720, the fifth gate electrode 735, and the ninth insulating interlayer 752, and may contact at least partially an upper surface of the first memory channel structure 462, where the second memory channel structure 820 may be in contact with the first capping pattern 452 of the first memory channel structure 462. The second memory channel structure 820 may be laterally shifted relative to the underlying first memory channel structure 462.

In example embodiments, the second channel 790 may include a lower portion extending through the seventh insulating interlayer 710 and having a first width, a middle portion extending through the etch stop layer 720 and having a second width, and an upper portion extending through the fifth gate electrode 735 and a lower portion of the ninth insulating interlayer 752 and having a third width. Each of the first and third widths may be greater than the second width. The middle portion extending through the etch stop layer 720 can be narrower than the upper portion extending through the fifth gate electrode 735 and a lower portion of the ninth insulating interlayer 752. The upper portion of the second channel 790 may have a shape of a cup, and the second filling pattern 800 may fill a space formed by the upper portion of the second channel 790. The upper portion of the second channel 790 may be on at least three sides of the second filling pattern 800.

The second charge storage structure 780 may extend through the fifth gate electrode 735 and the ninth insulating interlayer 752, and may cover a sidewall and a lower surface of an edge of the upper portion of the second channel 790. The second charge storage structure 780 may include a second tunnel insulation pattern, a second charge storage pattern and a third blocking pattern sequentially stacked in the horizontal direction from an outer sidewall of the second channel 790.

The second capping pattern 810 may contact upper surfaces of the second filling pattern 800 and the upper portion of the second channel 790, and may also contact an inner sidewall of the second charge storage structure 780.

In example embodiments, the second memory channel structure 820 may contact a corresponding one of the first memory channel structures 462, and thus a plurality of second memory channel structures 820 may be spaced apart from each other in the second and third directions D2 and D3 to form a second memory channel structure array.

The first and second channels 412 and 790 may include, e.g., undoped polysilicon, the first and second filling patterns 442 and 800 may include an oxide, e.g., silicon oxide, and the first and second capping patterns 452 and 810 may include, e.g., doped polysilicon.

The first tunnel insulation pattern 392 and the second tunnel insulation pattern may include an oxide, e.g., silicon oxide, the first charge storage pattern 382 and the second charge storage pattern may include a nitride, e.g., silicon nitride, and the first blocking pattern 372 and the third blocking pattern may include an oxide, e.g., silicon oxide.

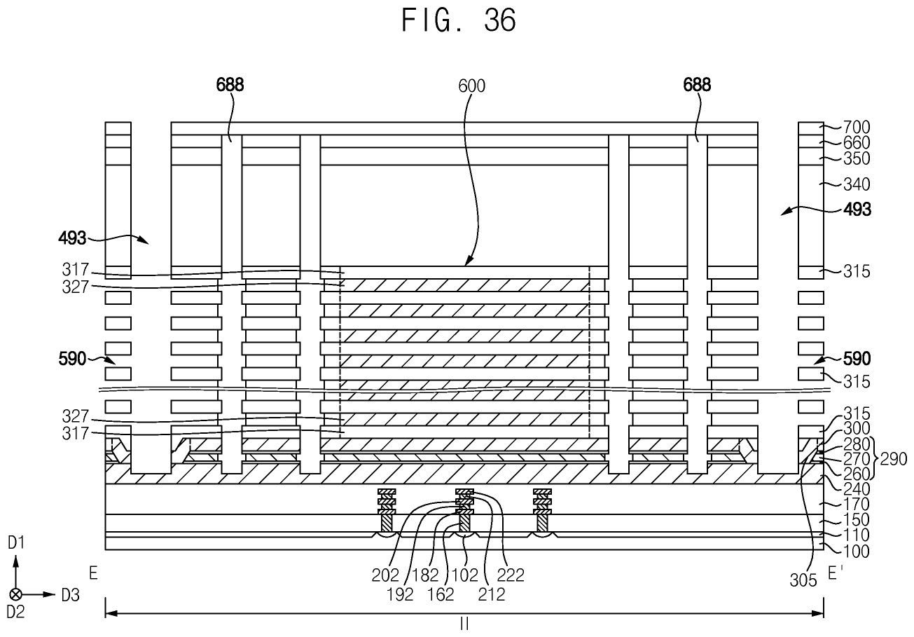

The insulation pattern structure 600 may extend through a portion of the gate electrode structure on the second region II of the substrate 100, and may have a shape of, e.g., a rectangle, an ellipse, a circuit, etc., in a plan view. In example embodiments, the insulation pattern structure 600 may extend through the second pad having a relatively large length in the second direction D2. The insulation pattern structure 600 may include sixth and seventh insulation patterns 317 and 327 alternately and repeatedly stacked in the first direction D1 (see e.g., FIG. 36). The sixth insulation pattern 317 may include an oxide, e.g., silicon oxide, and the seventh insulation pattern 327 may include a nitride, e.g., silicon nitride.

The second blocking pattern 615 may cover lower and upper surfaces of the first to fourth gate electrodes 751, 753, 755 and 757, and portions of sidewalls of the first to fourth gate electrodes 751, 753, 755 and 757 facing the first memory channel structure 462, the support structure 688 and the first to fourth upper contact plugs 851, 853, 855 and 857. The second blocking pattern 615 may include a metal oxide, e.g., aluminum oxide, hafnium oxide, etc.

The second insulation pad 324 may be formed on an upper surface of the insulation pattern structure 600, and the third insulation pad 326 may be formed on an upper surface of an end portion in the second direction D2 of the support layer 300. Each of the second and third insulation pads 324 and 326 may include a nitride, e.g., silicon nitride.

The third insulating interlayer 340 may be formed on the support layer 300, and may cover sidewalls of the first to fourth gate electrodes 751, 753, 755 and 757 and a sidewall of the first insulation pattern 315. The fourth insulating interlayer 350 may be formed on the third insulating interlayer 340 and the first insulation pattern 315 (see e.g., FIG. 3).

The fifth insulating interlayer 660, the seventh insulating interlayer 710 and the etch stop layer 720 may be sequentially stacked on the fourth insulating interlayer 350, and the eighth insulating interlayer 750 may be formed on the etch stop layer 720, and may cover a sidewall of the fifth gate electrode 735. Additionally, the ninth insulating interlayer 752 may be formed on the eighth insulating interlayer 750 and the fifth gate electrode 735, and the tenth to twelfth insulating interlayers 860, 880 and 900 may be sequentially stacked on the ninth insulating interlayer 752 (see e.g., FIG. 3).

Each of the first to fifth insulating interlayers 150, 170, 340, 350 and 660, each of the eighth to twelfth insulating interlayers 750, 752, 860, 880 and 900, and the etch stop layer 720 may include an oxide, e.g., silicon oxide, and the seventh insulating interlayer 710 may include a nitride, e.g., silicon nitride.

Each of the first to fourth upper contact plugs 851, 853, 855 and 857 may include a lower portion, which may extend through the third to fifth insulating interlayers 340, 350 and 660, the gate electrode structure, the first insulation pattern 315, the support layer 300, the sacrificial layer structure 290, the CSP 240 and an upper portion of the second insulating interlayer 170 to contact an upper surface of a corresponding one of the tenth to thirteenth lower wirings 221, 223, 225 and 227, and an upper portion on the lower portion, which may extend through seventh insulating interlayer 710, the etch stop layer 720 and the eighth and ninth insulating interlayers 750 and 752. An upper surface of the lower portion of the first contact plug 851 can be substantially coplanar with an upper surface of the first memory channel structure, and an upper surface of the upper portion of the first contact plug 851 can be substantially coplanar with an upper surface of the second memory channel structure.

In example embodiments, each of the lower portion and the upper portion of each of the first to fourth upper contact plugs 851, 853, 855 and 857 may have a width gradually increasing from a bottom toward a top thereof, and an upper surface of the lower portion may have an area greater than an area of a lower surface of the upper portion. The lower portion of each of the first to fourth upper contact plugs 851, 853, 855 and 857 can have a width varying in the first direction, and the upper portion of each of the first to fourth upper contact plugs 851, 853, 855 and 857 can have a width gradually increasing from a bottom toward a top thereof.

In example embodiments, the first upper contact plug 851 may extend through a pad of the first gate electrode 751, the second upper contact plug 853 may extend through a pad of the second gate electrodes 753 and the first gate electrode 751, the third upper contact plug 855 may extend through a pad of a first one of the second gate electrodes 753, second ones of the second gate electrodes 753 under the first one of the second gate electrodes 753, and the first and second gate electrodes 751 and 753, and the fourth upper contact plug 857 may extend through a pad of a first one of the fourth gate electrodes 757, second ones of the fourth gate electrodes 757 under the first one of the fourth gate electrodes 757, and the first to third gate electrodes 751, 753 and 755.

In example embodiments, a contact plug can include a lower portion and an upper portion, where the upper portion can be on and in contact with an upper surface of the lower portion. The lower portion of the contact plug can extend partially through the gate electrode structure. The lower portion of the contact plug can extend through the first, second and third gate electrodes of the gate electrode structure, where the lower portion of the contact plug may be electrically insulated from the first and second gate electrodes 751, 753, but is electrically connected to the third gate electrode 755. The lower portion of each of the second contact plugs may extend through the first and second gate electrodes, where the lower portion of each of the second contact plugs may be electrically insulated from the first gate electrode 751, and is electrically connected to the second gate electrode 753.

In example embodiments, each of the first to fourth upper contact plugs 851, 853, 855 and 857 may include protrusion portions, which may protrude in the horizontal direction, at respective portions of a sidewall facing the first to fourth gate electrodes 751, 753, 755 and 757. Thus, a plurality of protrusion portions may be spaced apart from each other in the first direction D1. An uppermost one of the protrusion portions of each of the first to fourth upper contact plugs 851, 853, 855 and 857 may have a width in the horizontal direction greater than widths in the horizontal direction of other ones of the protrusion portions of each of the first to fourth upper contact plugs 851, 853, 855 and 857. The protrusion portions of each of the first to fourth upper contact plugs 851, 853, 855 and 857 may have a width greater than portions of the first to fourth upper contact plugs 851, 853, 855 and 857 above and below the protrusion portions. The first contact plug 851 can include protrusion portions on portions of a sidewall of the first contact plug facing the first, second and third gate electrodes 751, 753, 755, respectively, the protrusion portion protruding in a horizontal direction substantially parallel to the upper surface of the substrate 100.

In example embodiments, a first one of the gate electrodes having a pad through which one of the first to fourth upper contact plugs 851, 853, 855 and 857 extend may directly contact the one of the first to fourth upper contact plugs 851, 853, 855 and 857, while each of second ones of the gate electrodes under the first one may be spaced apart from the one of the first to fourth upper contact plugs 851, 853, 855 and 857 by the second insulation pattern 683 and the second blocking pattern 615. The third insulation pattern 685 may be disposed between each of the first to fourth upper contact plugs 851, 853, 855 and 857 and the second sacrificial layer 270.

Each of the second and third insulation patterns 683 and 685 may include an oxide, e.g., silicon oxide (see e.g., FIG. 4).

The fifth upper contact plug 856 may include a lower portion, which may extend through the third to fifth insulating interlayers 340, 350 and 660, the support layer 300, the sacrificial layer structure 290, the CSP 240 and the upper portion of the second insulating interlayer 170 to contact an upper surface of the fourteenth lower wiring 229, and an upper portion on the lower portion, which may extend through the seventh insulating interlayer 710, the etch stop layer 720 and the eighth and ninth insulating interlayers 750 and 752 (see e.g., FIG. 3).

Additionally, the sixth upper contact plug 859 may include a lower portion, which may extend through the third to fifth insulating interlayers 340, 350 and 660, the second insulation pad 324, the insulation pattern structure 600, the support layer 300, the sacrificial layer structure 290, the CSP 240 and the upper portion of the second insulating interlayer 170 to contact an upper surface of the eighth lower wiring 222, and an upper portion on the lower portion, which may extend through the seventh insulating interlayer 710, the etch stop layer 720 and the eighth and ninth insulating interlayers 750 and 752 (see e.g., FIG. 3).

Each of the lower portion and the upper portion of each of the fifth and sixth upper contact plugs 856 and 859 may have a width gradually increasing from a bottom toward a top thereof, and an upper surface of the lower portion may be greater than a lower surface of the upper portion.

Sidewalls of the fifth and sixth upper contact plugs 856 and 859 may be covered by the fourth and fifth insulation patterns 686 and 689, respectively. Each of the fourth and fifth insulation patterns 686 and 689 may include an oxide, e.g., silicon oxide.

The seventh contact plug 858 may extend through the ninth insulating interlayer 752, and may contact an upper surface of the fifth gate electrode 735.

In example embodiments, upper surfaces of the first to seventh upper contact plugs 851, 853, 855, 857, 856, 859 and 858 may be substantially coplanar with each other.

Each of the eighth upper contact plugs 870 may extend through the tenth insulating interlayer 860, and may contact an upper surface of a corresponding one of the first to seventh upper contact plugs 851, 853, 855, 857, 856, 859 and 858 and the second memory channel structure 820. Each of the upper vias 890 may extend through the eleventh insulating interlayer 880, and may contact an upper surface of a corresponding one of the eighth contact plugs 870. Each of the upper wirings 910 may extend through the twelfth insulating interlayer 900, and may contact an upper surface of a corresponding one of the upper vias 890.

In example embodiments, each of ones of the upper wirings 910 may extend in the third direction D3, and the ones of the upper wirings 910 may be spaced apart from each other in the second direction D2. Each of the ones of the upper wirings 910 may serve as a bit line.

In example embodiments, the upper wirings 910, the upper vias 890 and the eighth upper contact plugs 870 may have various layouts, and in some cases, more upper wirings and more upper vias may be further formed at upper levels.

The first to eighth upper contact plugs 851, 853, 855, 857, 856, 859, 858 and 870, the upper vias 890 and the upper wirings 910 may include a conductive material, e.g., a metal, a metal nitride, a metal silicide, etc.

In example embodiments of the semiconductor device, each of the first to fourth upper contact plugs 851, 853, 855 and 857 may extend through and contact a corresponding one of the first to fourth gate electrodes 751, 753, 755 and 757 to be electrically connected thereto, and may be formed by the same process that is illustrated below. Accordingly, the process for forming the first to fourth upper contact plugs 851, 853, 855 and 857 may be simplified and cost for forming the first to fourth upper contact plugs 851, 853, 855 and 857 may decrease, when compared to a case in which some of the first to fourth upper contact plugs 851, 853, 855 and 857 are separately formed from others.

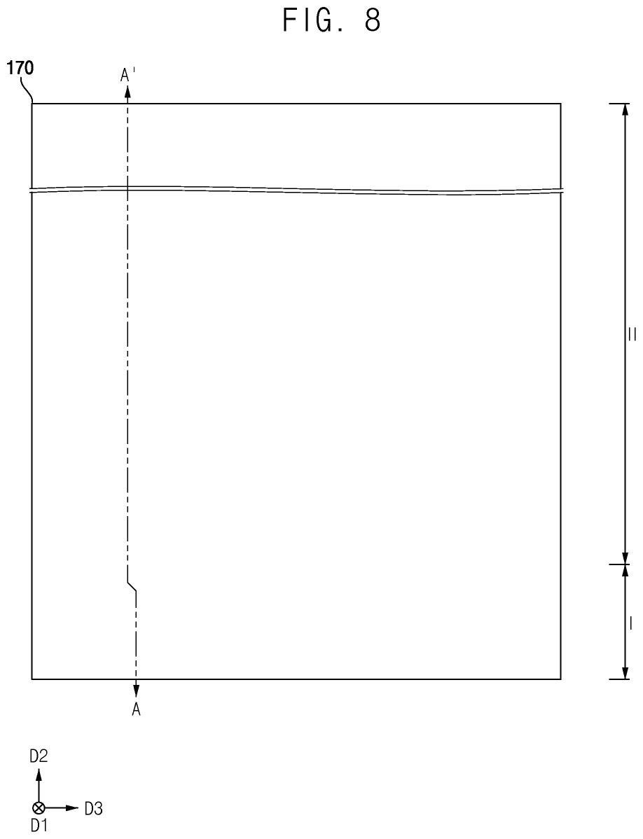

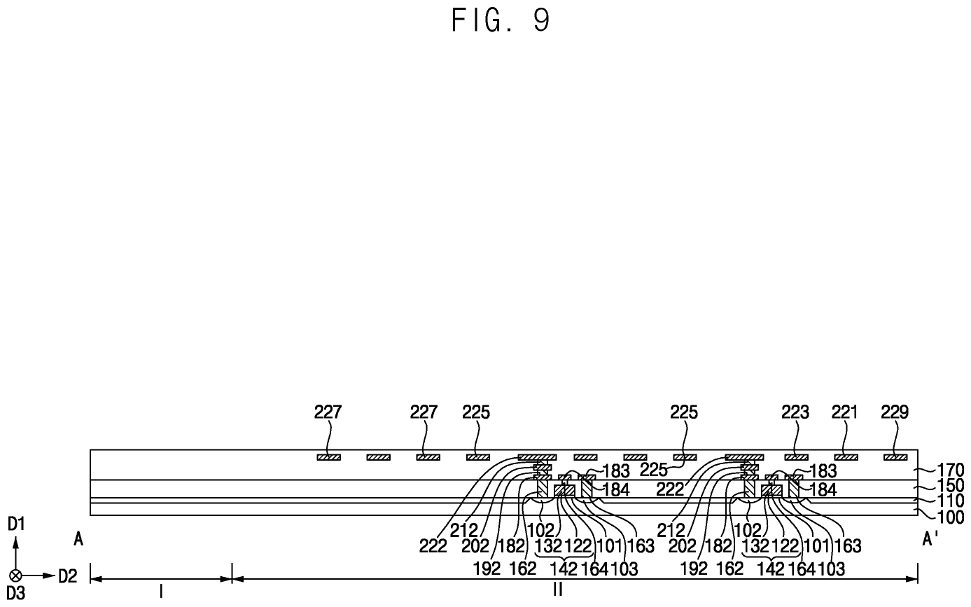

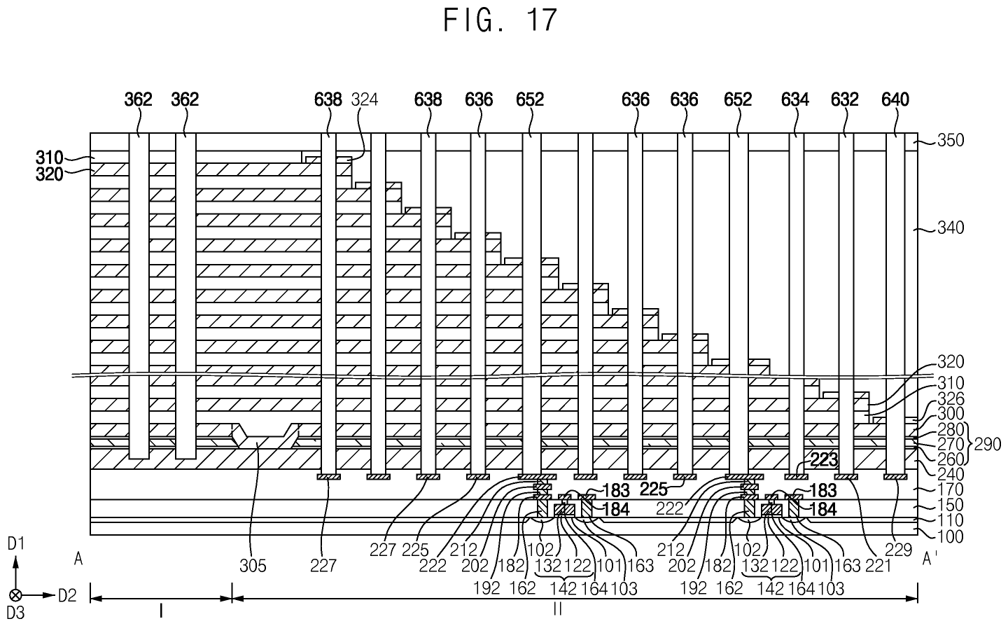

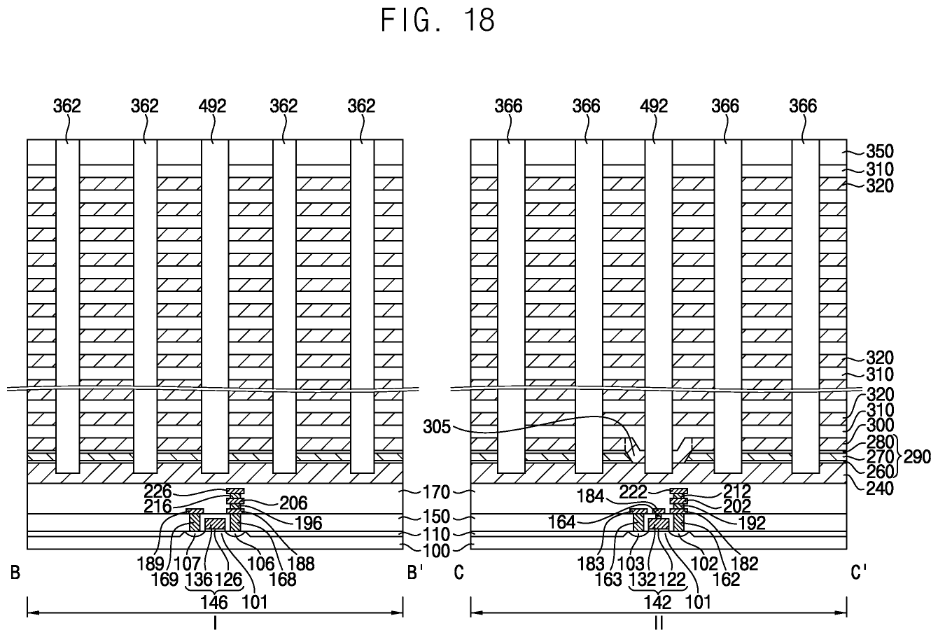

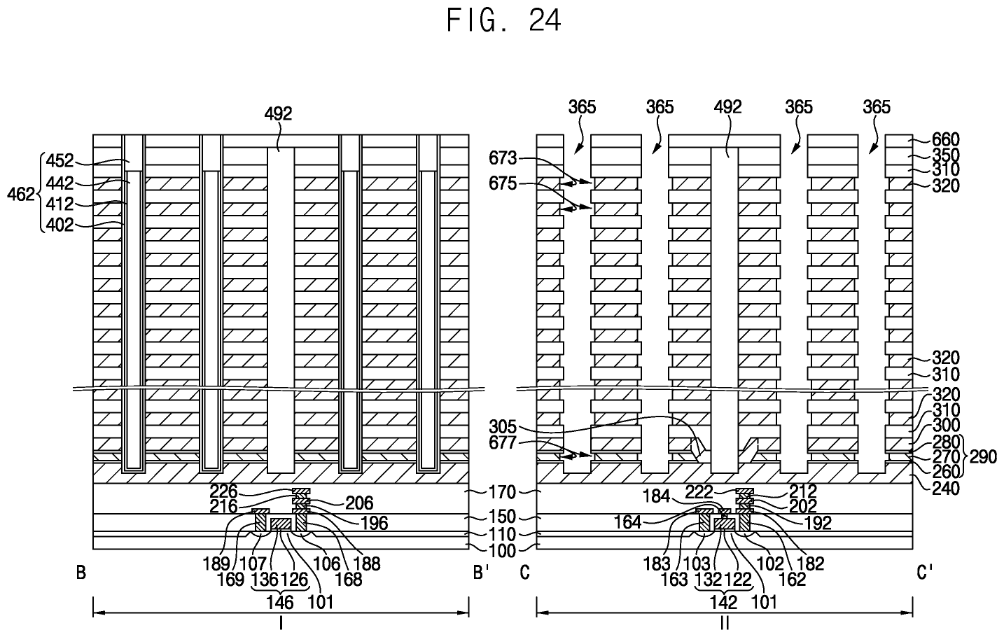

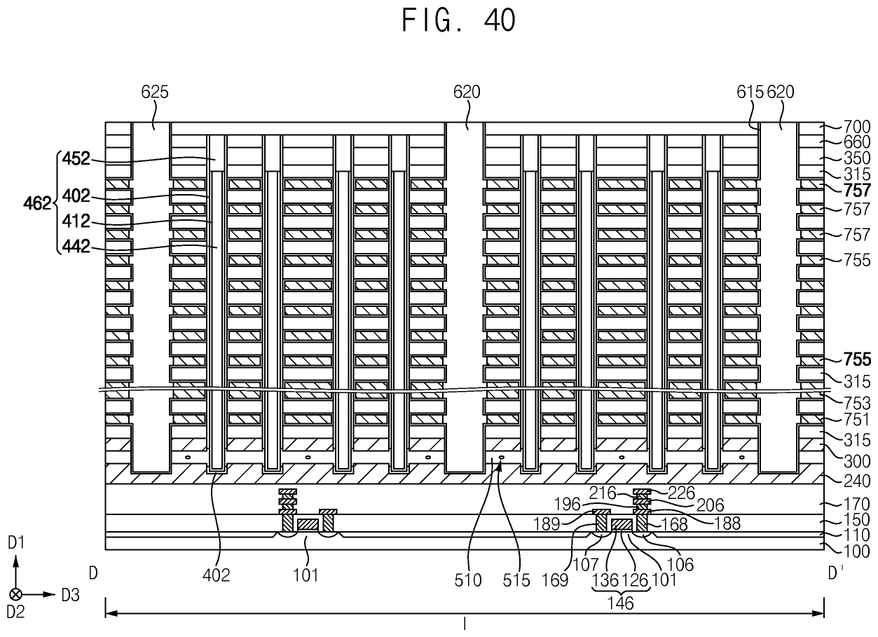

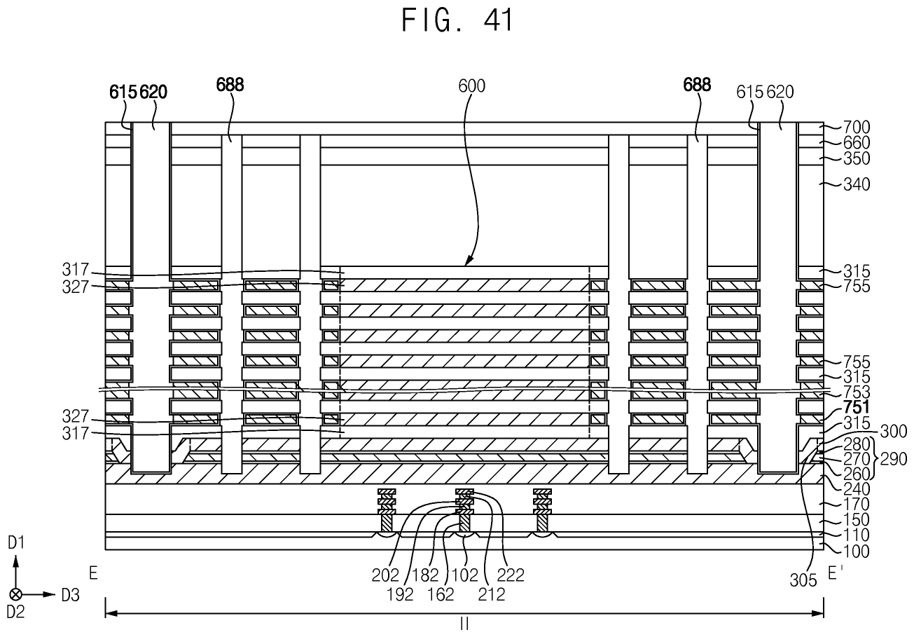

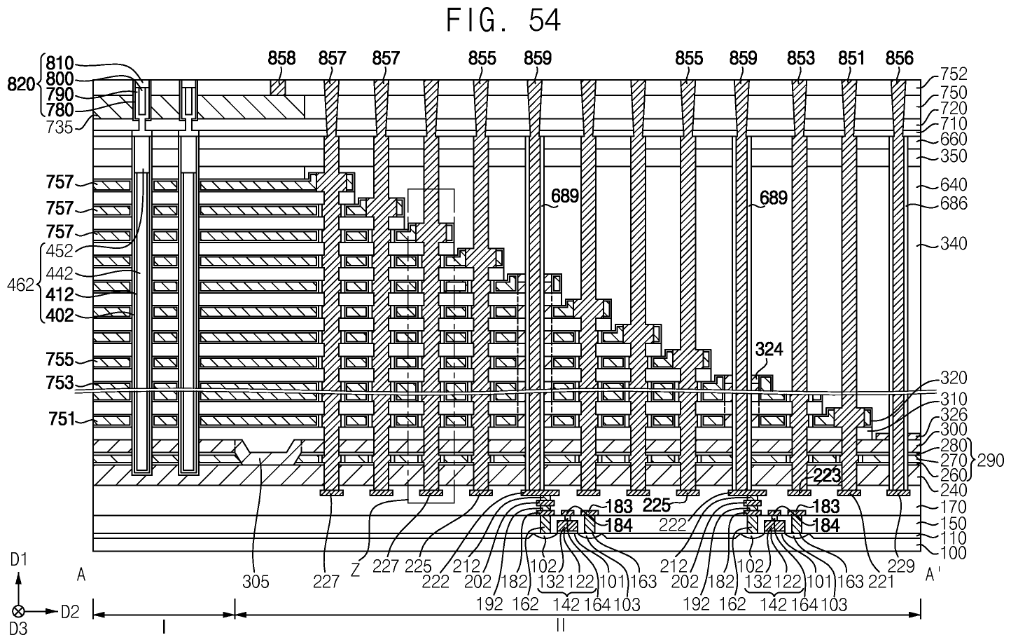

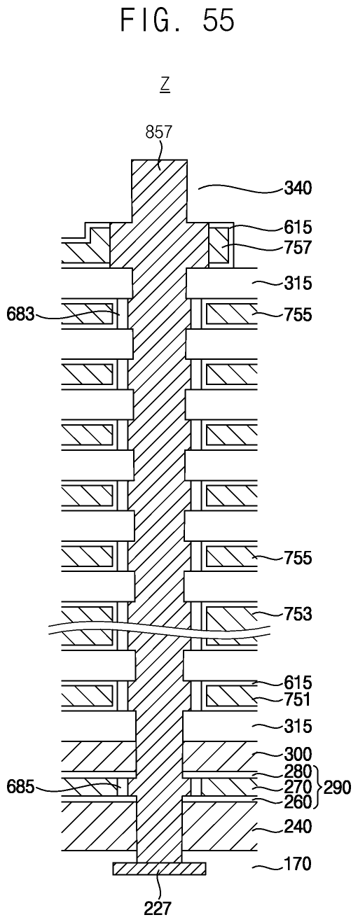

FIGS. 8 to 55 are plan views and cross-sectional views illustrating a method of manufacturing a semiconductor device in accordance with example embodiments. Particularly, FIGS. 8, 13, 16, 29, 31, 39, 43, 45, 48 and 53 are the plan views, and FIGS. 9-12, 14-15, 17-28, 30, 32-38, 40-42, 44, 46-47, 59-52 and 54-55 are the cross-sectional views.

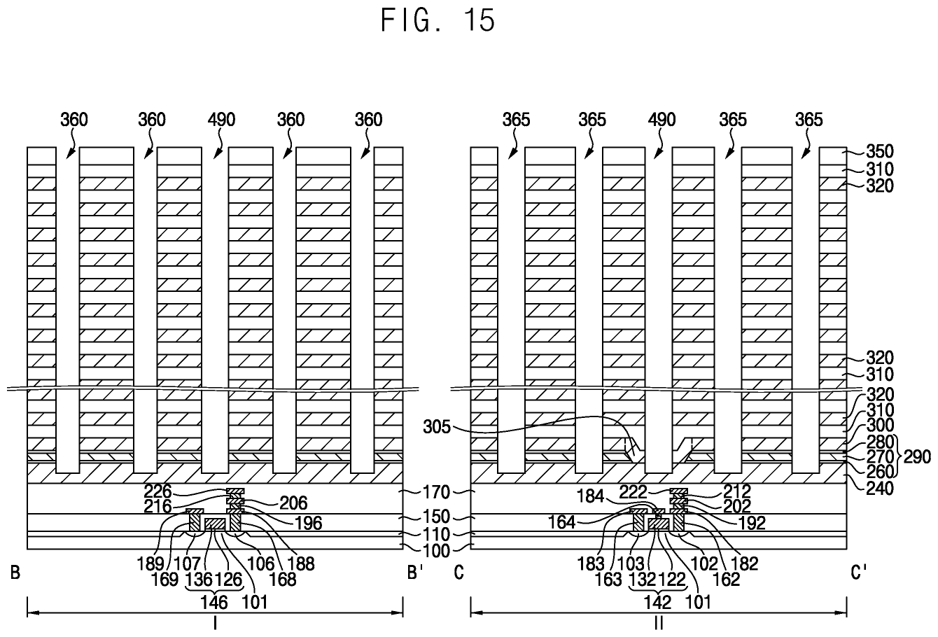

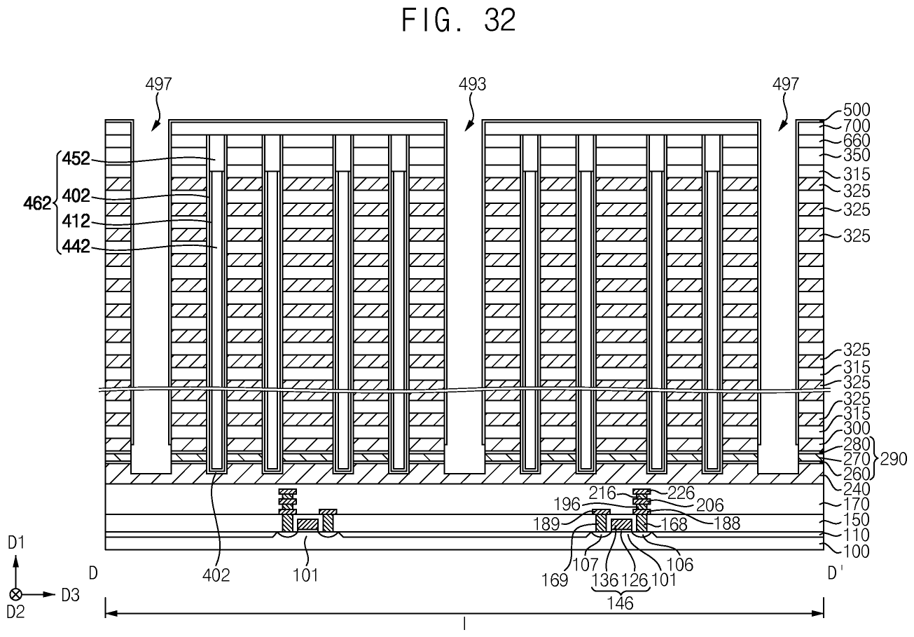

FIGS. 9-12, 14, 17, 22-23, 25, 27-28, 50-52 and 54-55 are cross-sectional views taken along lines A-A′ of corresponding plan views, respectively, each of FIGS. 15, 18-21, 24, 26 and 30 includes cross-sectional views taken along lines B-B′ and C-C′, respectively, of corresponding plan views, respectively, FIGS. 32-35, 37, 40, 42, 44, 46-47 and 49 are cross-sectional views taken along lines D-D′ of corresponding plan views, respectively, and FIGS. 36, 38 and 41 are cross-sectional views taken along lines E-E′ of corresponding plan views, respectively.

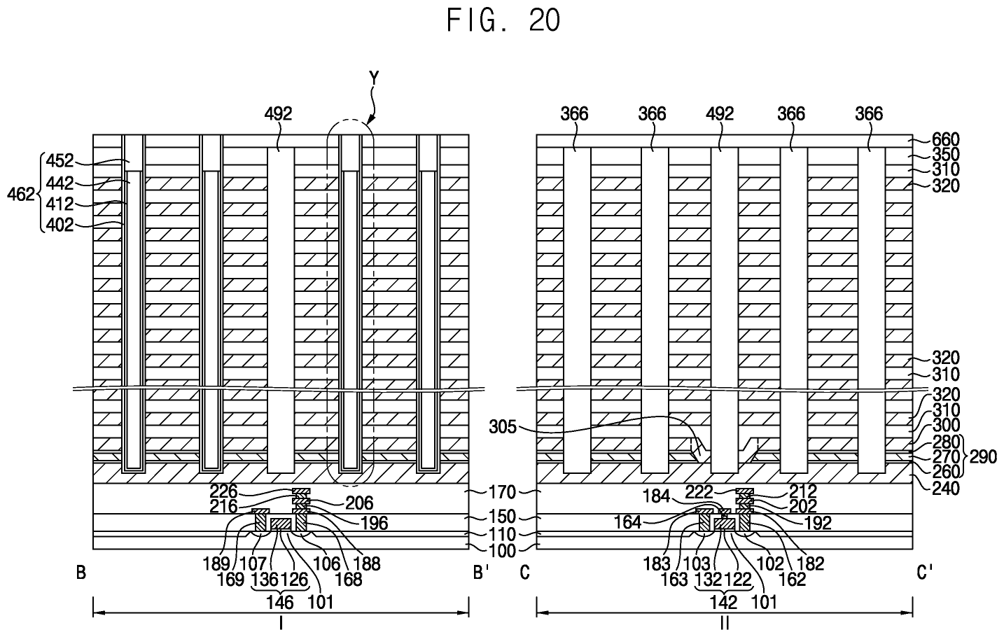

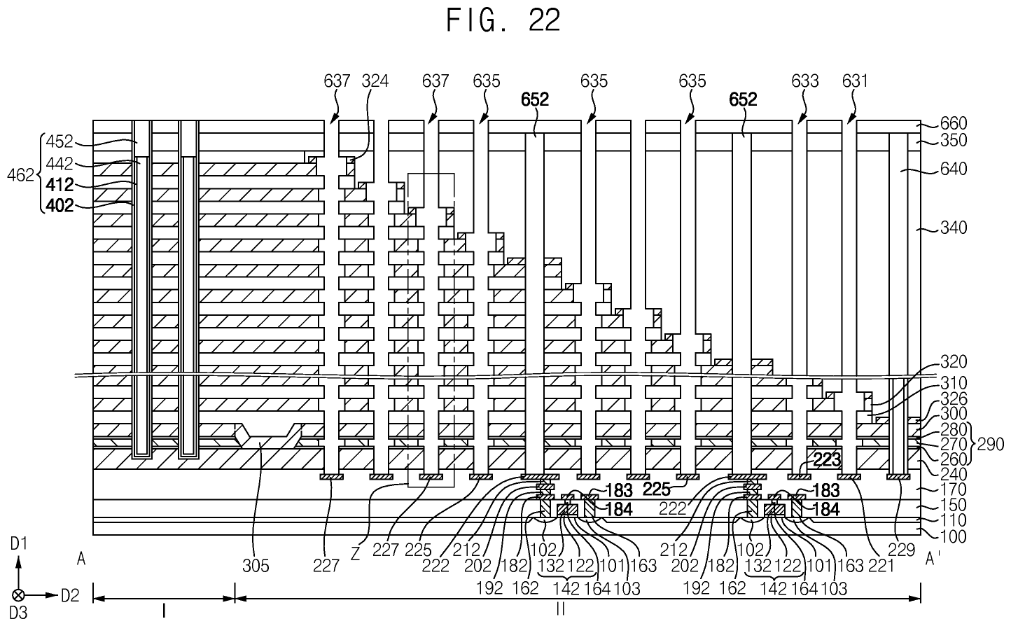

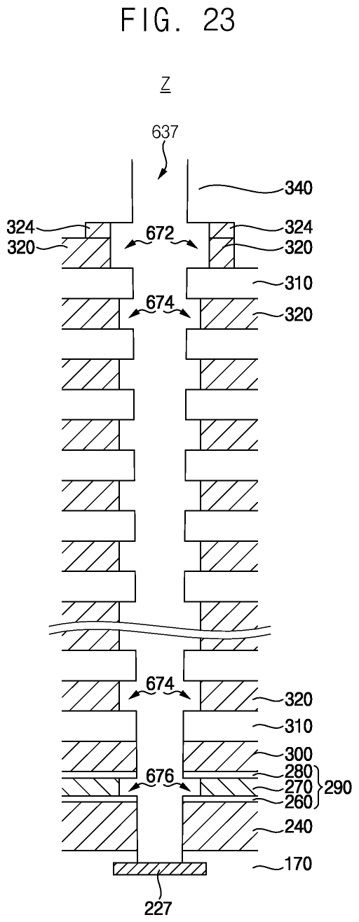

FIGS. 8 to 55 are drawings of region X of FIG. 1, FIG. 21 is an enlarged cross-sectional view of region Y of FIG. 20, and FIGS. 23, 25, 28, 51 and 55 are enlarged cross-sectional views of region Z of FIGS. 22, 24, 27, 50 and 54, respectively.

Referring to FIGS. 8 and 9, a lower circuit pattern may be formed on a substrate 100, and first and second insulating interlayers 150 and 170 covering the lower circuit pattern may be sequentially formed on the substrate 100.

Elements of the lower circuit pattern may be formed by, e.g., a patterning process or a damascene process.

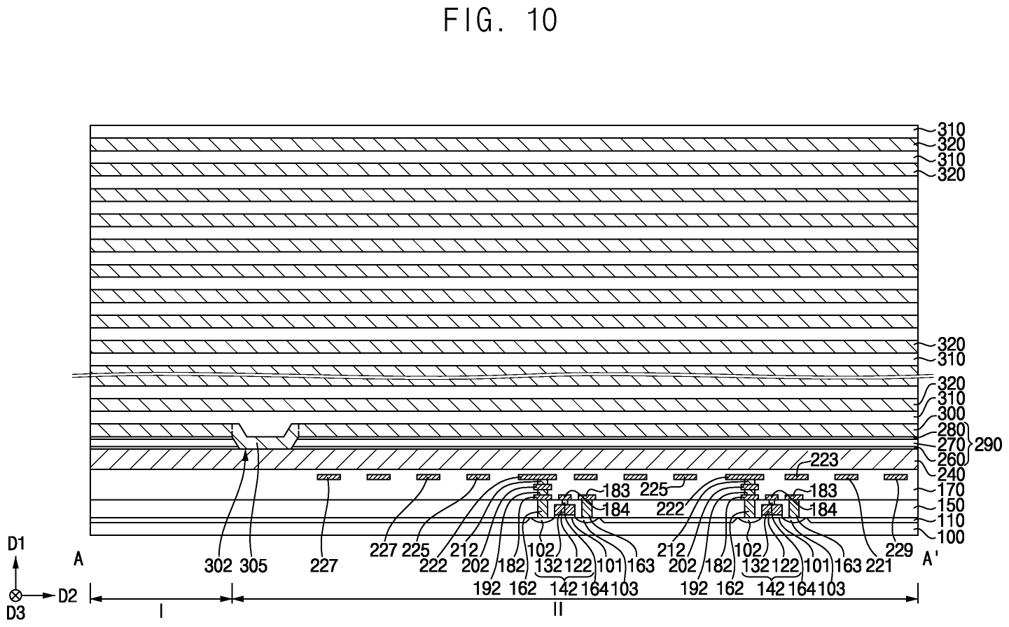

Referring to FIG. 10, a common source plate (CSP) 240 and a sacrificial layer structure 290 may be sequentially formed on the second insulating interlayer 170, the sacrificial layer structure 290 may be partially removed to form a first opening 302 exposing an upper surface of the CSP 240, and a support layer 300 may be formed on an upper surface of the sacrificial layer structure 290 and the exposed upper surface of the CSP 240, where the portion of the support layer 300 in the first opening 302 can form a support pattern 305. The support layer 300 can fill in the first opening 302 and be planarized to form a surface for subsequent layers.

The sacrificial layer structure 290 may include first, second and third sacrificial layers 260, 270 and 280 sequentially stacked. Each of the first and third sacrificial layers 260 and 280 may include an oxide, e.g., silicon oxide, and the second sacrificial layer 270 may include a nitride, e.g., silicon nitride.

The first opening 302 may have various layouts in a plan view. For example, a plurality of first openings 302 may be spaced apart from each other in the second and third directions D2 and D3 on the first region I of the substrate 100, a first opening 302 may extend in the third direction D3 on a portion of the second region II adjacent to the first region I of the substrate 100, and a plurality of first openings each of which may extend in the second direction D2 may be spaced apart from each other in the third direction D3 on the second region II of the substrate 100. FIG. 10 shows the first opening 302 extending in the third direction D3 on the portion of the second region II adjacent to the first region I of the substrate 100.

In example embodiments, the support layer 300 may include a material having an etching selectivity with respect to the first to third sacrificial layers 260, 270 and 280, e.g., polysilicon doped with n-type impurities. The support layer 300 may be conformally formed, and thus a first recess may be formed on a portion of the support layer 300 in the first opening 302. Hereinafter, the portion of the support layer 300 in the first opening 302 may be referred to as a support pattern 305.

In examples embodiments, a first insulation layer 310 and a fourth sacrificial layer 320 may be alternately and repeatedly stacked in the first direction D1 on the support layer 300 and the support pattern 305, and thus a mold layer including the first insulation layers 310 and the fourth sacrificial layers 320. The first insulation layer 310 may include an oxide, e.g., silicon oxide, and the fourth sacrificial layer 320 may include a material having an etching selectivity with respect to the first insulation layer 310, e.g., a nitride such as silicon nitride.

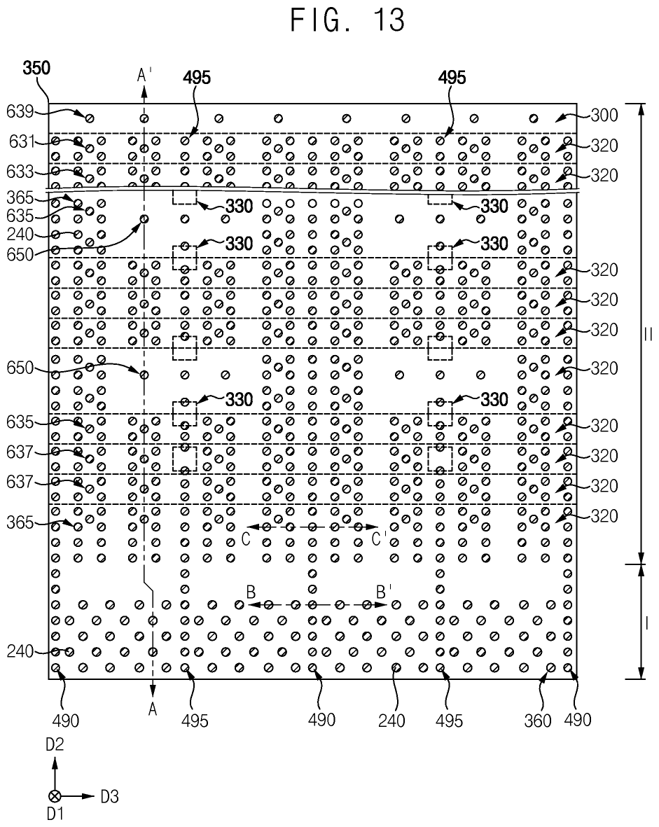

Referring to FIG. 10 together with FIG. 13, a first division pattern 330 may be formed through a portion of a lowermost one of the fourth sacrificial layers 320. The first division pattern 330 may be formed on the second region II of the substrate 100. In example embodiments, a plurality of first division patterns 330 may be spaced apart from each other in the second and third directions D2 and D3.

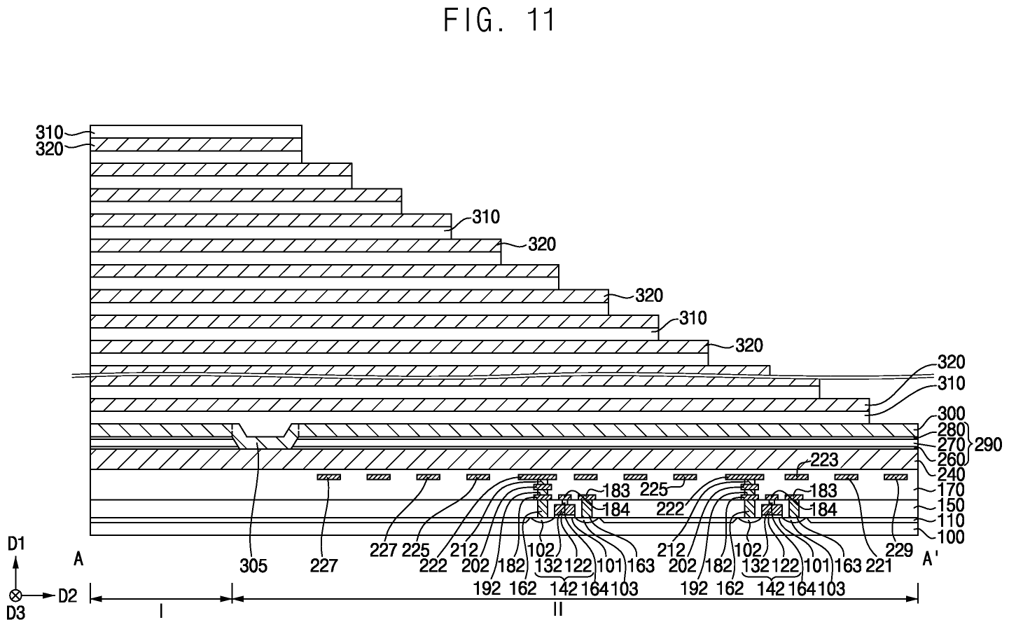

Referring to FIG. 11, a photoresist pattern may be formed on an uppermost one of the first insulation layers 310, and the uppermost one of the first insulation layers 310 and an uppermost one of the fourth sacrificial layers 320 may be etched using the photoresist pattern as an etching mask. Thus, one of the first insulation layers 310 under the uppermost one of the fourth sacrificial layers 320 may be partially exposed.

A trimming process for reducing an area of the photoresist pattern may be performed, and the uppermost one of the first insulation layers 310, the uppermost one of the fourth sacrificial layers 320, the partially exposed one of the first insulation layers 310 and one of the fourth sacrificial layers 320 under the partially exposed one of the first insulation layers 310 may be etched by an etching process using the reduced photoresist pattern as an etching mask. The trimming process and the etching process may be repeatedly performed to form a mold including a plurality of step layers each of which may include the first insulation layer 310 and the fourth sacrificial layer 320 sequentially stacked and having a staircase shape.

Hereinafter, the “step layer” may refer to both of an exposed portion and non-exposed portion of a pair of the first insulation layer 310 and the fourth sacrificial layer 320, and the exposed portion of the step layer that is not covered by upper step layers may be referred to as a “step.” In example embodiments, the steps may be arranged in the second direction D2. Alternatively, the steps may be arranged in the third direction D3.

In example embodiments, lengths in the second direction D2 of the steps of the mold may be substantially constant except for ones of the steps. The lengths of the ones of the steps may be greater than lengths of other ones of the steps. Hereinafter, the ones of the steps having a relatively large length in the second direction D2 may be referred to as second steps, and the other ones of the steps having a relatively small length in the second direction D2 may be referred to as first steps. FIG. 11 shows two second steps. In each plan view after FIG. 13, the steps are indicated with dotted lines.

The mold may be formed on the support layer 300 and the support pattern 305 on the first and second regions I and II of the substrate 100, and an upper surface of an edge portion of the support layer 300 may not be covered by the mold, but may be exposed. Each step of the mold may be disposed on the second region II of the substrate 100.

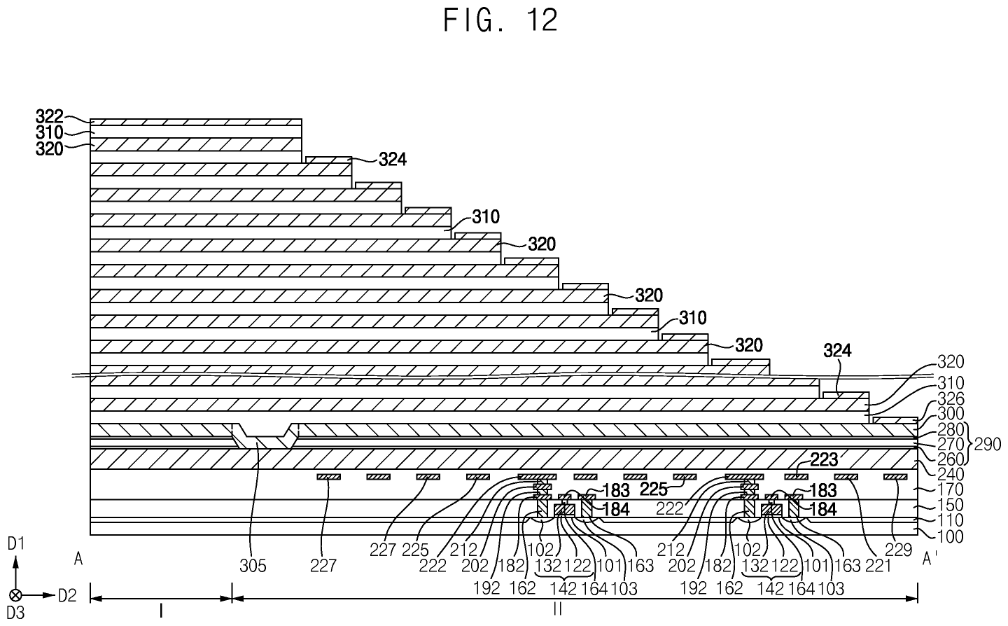

Referring to FIG. 12, an insulation pad layer may be formed on the mold and the support layer 300, and may be partially removed to form first, second and third pads 322, 324 and 326.

In an example embodiment, the insulation pad layer may include a material substantially the same as a material of the fourth sacrificial layer 320, however, an etching rate of the insulation pad layer may be different from an etching rate of the fourth sacrificial layer 320.

After forming the insulation pad layer, portions of the insulation pad layer adjacent to the steps may be removed to form a first insulation pad 322 on an upper surface of the uppermost one of the first insulation layers 310, a second insulation pad 324 on a portion of the fourth sacrificial layer 320 of each step in the mold, and a third insulation pad 326 on the support layer 300. In example embodiments, each of the first to third insulation pads 322, 324 and 326 may extend in the third direction D3.

Referring to FIGS. 13 to 15, a third insulating interlayer 340 may be formed on the CSP 240 to cover the mold, the support layer 300 and the first to third insulation pads 322, 324 and 326, and the third insulating interlayer 340 may be planarized until an upper surface of the first insulation layer 310 included in an uppermost step layer is exposed. A fourth insulating interlayer 350 can be formed on the third insulating interlayer 340 and first insulation layer 310.

During the planarization process, the first insulation pad 322, the uppermost one of the first insulation layers 310, and the fourth sacrificial layer 320 included in the uppermost step layer may also be removed, and a sidewall of the mold may be covered by the third insulating interlayer 340.

An etching process may be performed to form a first hole 360 extending through the fourth insulating interlayer 350, the mold, the support layer 300 and the sacrificial layer structure 290 in the first direction D1 to expose an upper surface of the CSP 240 on the first region I of the substrate 100, and a second hole 365 extending through the third and fourth insulating interlayers 340 and 350, a portion of the mold, the support layer 300 and the sacrificial layer structure 290 in the first direction D1 to expose the upper surface of the CSP 240 on the second region II of the substrate 100 (see e.g., FIG. 15). In example embodiments, a plurality of first holes 360 may be spaced apart from each other in the second and third directions D2 and D3 on the first region I of the substrate 100, and a plurality of second holes 365 may be spaced apart from each other in the second and third directions D2 and D3 on the second region II of the substrate 100.

Additionally, an etching process may be performed to form third and fourth holes 490 and 495 extending through the third and fourth insulating interlayers 340 and 350, the mold, the support layer 300 and the sacrificial layer structure 290 in the first direction D1 to expose the upper surface of the CSP 240 on the first and second regions I and II of the substrate 100.

The first to fourth holes 360, 365, 490 and 495 may be formed simultaneously by the same etching process, or sequentially formed. In example embodiments, the etching process may be performed until the upper surface of the CSP 240 is exposed, and further, the first to fourth holes 360, 365, 490 and 495 may extend through an upper portion of the CSP 240, where a lower surface of first to fourth holes 360, 365, 490 and 495 can expose CSP 240.

In example embodiments, a plurality of third holes 490 may be spaced apart from each other in the second direction D2 by a first distance on the first and second regions I and II of the substrate 100, and may be arranged to opposite end portions in the second direction D2 of the mold. Additionally, a plurality of third holes 490 may be spaced apart from each other in the third direction D3.

In example embodiments, a plurality of fourth holes 495 may be spaced apart from each other in the second direction D2 between ones of the third holes 490 neighboring in the third direction D3. However, the fourth holes 495 may be spaced apart from each other in the second direction D2 by the first distance on the first region I of the substrate 100, while fourth hole groups each of which may include the fourth holes 495 spaced apart from each other in the second direction D2 by the first distance may be spaced apart from each other in the second direction D2 by a second distance greater than the first distance.

In example embodiments, ones of the fourth holes 495 may extend through a portion of the first division pattern 330.

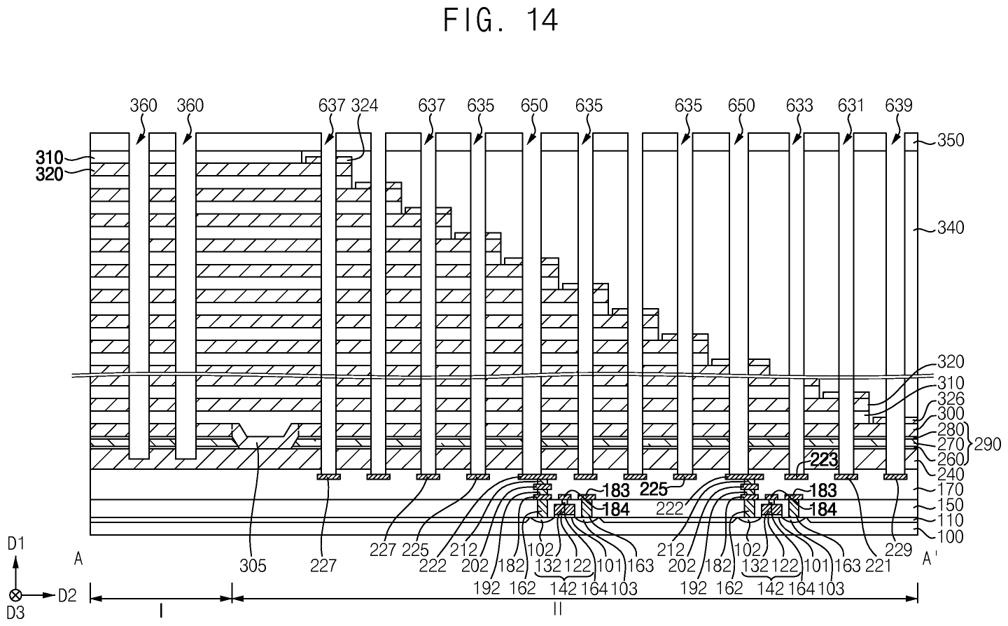

Fifth to eighth holes 631, 633, 635 and 637 extending through the third and fourth insulating interlayers 340 and 350, the second insulation pad 324, the mold, the support layer 300, the sacrificial layer structure 290, the CSP 240 and an upper portion of the second insulating interlayer 170 in the first direction D1 to expose upper surfaces of the tenth to thirteenth lower wirings 221, 223, 225 and 227, respectively, and a tenth hole 650 extending through the third and fourth insulating interlayers 340 and 350, the second insulation pad 324, the mold, the support layer 300, the sacrificial layer structure 290, the CSP 240 and the upper portion of the second insulating interlayer 170 in the first direction D1 to expose an upper surfaces of the eighth lower wiring 222 may be formed on the second region II of the substrate 100. Additionally, a ninth hole 639 extending through the third and fourth insulating interlayers 340 and 350, the third insulation pad 326, the mold, the support layer 300, the sacrificial layer structure 290, the CSP 240 and the upper portion of the second insulating interlayer 170 in the first direction D1 to expose an upper surface of the fourteenth lower wiring 229 may be formed (see e.g., FIG. 14).

In example embodiments, each of the fifth to eighth holes 631, 633, 635 and 637 may be formed in an area that may be surrounded by the second holes 365 in a plan view. For example, the second holes 365 may be arranged at respective vertices of a rectangle, and each of the fifth to eighth holes 631, 633, 635 and 637 may be disposed in an inside of the rectangle in a plan view.

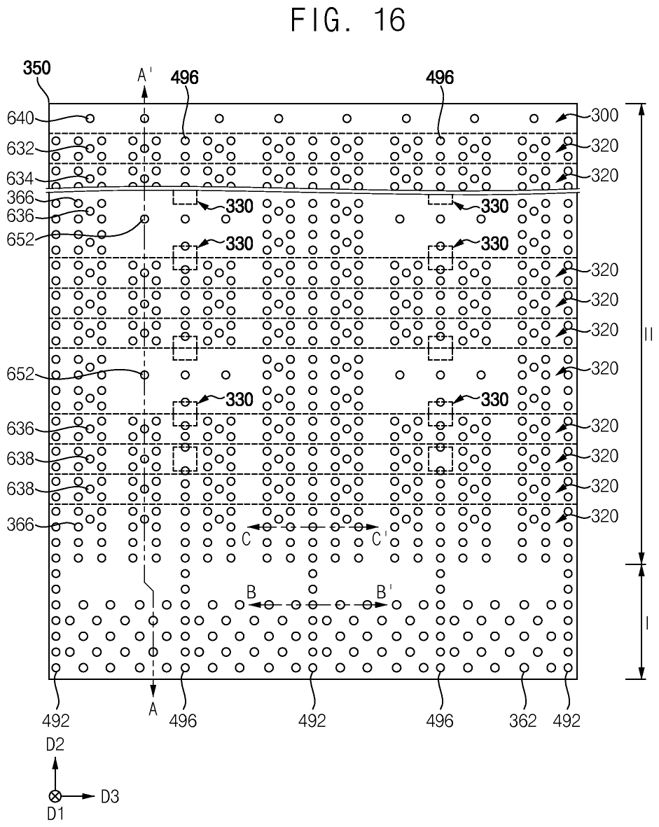

Referring to FIGS. 16 to 18, fifth to fourteenth sacrificial patterns 362, 366, 492, 496, 632, 634, 636, 638, 640 and 652 may be formed in the first to tenth holes 360, 365, 490, 495, 631, 633, 635, 637, 639 and 650, respectively.

The fifth to fourteenth sacrificial patterns 362, 366, 492, 496, 632, 634, 636, 638, 640 and 652 may be formed by forming a fifth sacrificial layer on the CSP 240, the eighth lower wiring 222, the tenth to fourteenth lower wirings 222, 221, 223, 225, 227, 229, and the fourth insulating interlayer 350 to fill the first to tenth holes 360, 365, 490, 495, 631, 633, 635, 637, 639 and 650, and planarizing the fifth sacrificial layer until an upper surface of the fourth insulating interlayer 350 is exposed.

The fifth sacrificial layer may include an oxide, e.g., silicon oxide.

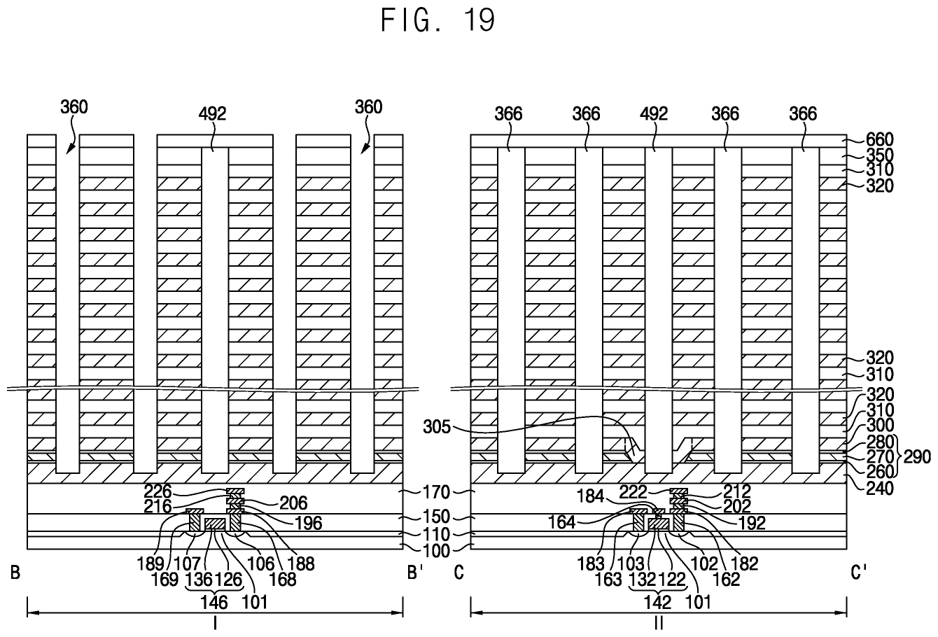

Referring to FIG. 19, a fifth insulating interlayer 660 may be formed on the fourth insulating interlayer 350 and the fifth to fourteenth sacrificial patterns 362, 366, 492, 496, 632, 634, 636, 638, 640 and 652, the fifth insulating interlayer 660 may be patterned by an etching process to form a fifth sacrificial pattern 362, and the exposed fifth sacrificial pattern 362 may be removed to form the first hole 360 exposing the upper surface of the CSP 240 again.

Referring to FIGS. 20 and 21, a first charge storage structure layer and a first channel layer may be sequentially formed on a sidewall of the first hole 360, the exposed upper surface of the CSP 240 and an upper surface of the fifth insulating interlayer 660, and a first filling layer may be formed on the first channel layer to fill the first hole 360.

The first charge storage structure layer may include a first blocking layer, a first charge storage layer and a first tunnel insulation layer sequentially stacked.

The first filling layer, the first channel layer and the first charge storage structure layer may be planarized until the upper surface of the fifth insulating interlayer 660 is exposed. Thus, a first charge storage structure 402, a first channel 412 and a first filling pattern 442 may be formed in the first hole 360. The first charge storage structure 402 may include a first blocking pattern 372, a first charge storage pattern 382 and a first tunnel insulation pattern 392 sequentially stacked (see e.g., FIG. 21).

Upper portions of the first filling pattern 442 and the first channel 412 may be removed to form a second recess, and a first capping pattern 452 may be formed in the second recess.

The first charge storage structure 402, the first channel 412, the first filling pattern 442 and the first capping pattern 452 in the first hole 360 may collectively form a first memory channel structure 462.

In example embodiments, the first memory channel structure 462 may have a shape of a pillar extending in the first direction D1. A plurality of first memory channel structures 462 may be spaced apart from each other in the second and third directions D2 and D3 on the first region I of the substrate 100.

Referring to FIGS. 22 to 24, the fifth insulating interlayer 660 may be patterned by an etching process to expose the ninth to twelfth sacrificial patterns 632, 634, 636 and 638, and the exposed ninth to twelfth sacrificial patterns 632, 634, 636 and 638 may be removed to form the fifth to eighth holes 631, 633, 635 and 637 exposing the upper surfaces of the tenth to thirteenth lower wirings 221, 223, 225 and 227, respectively, again.

During the etching process, the sixth sacrificial pattern 366 may also be exposed, and the exposed sixth sacrificial pattern 366 may be removed to form the second hole 365 exposing the upper surface of the CSP 240 again.

An additional etching process may be performed to remove portions of the fourth sacrificial layer 320 adjacent to each of the fifth to eighth holes 631, 633, 635 and 637 so that third and fourth recesses 672 and 674 may be formed, and portions of the second sacrificial layer 270 adjacent to the fifth to eighth holes 631, 633, 635 and 637 may also be removed to form a fifth recess 676.

In example embodiments, when the third recess 672 is formed, not only the fourth sacrificial layer 320 but also the second insulation pad 324 may be removed, so that the third recess 672 may have a horizontal depth greater than a horizontal depth of the second recess 674.

During the additional etching process, portions of the fourth sacrificial layer 320 and the second sacrificial layer 270 adjacent to the second hole 365 may also be removed to form sixth to eighth recesses 673, 675 and 677.

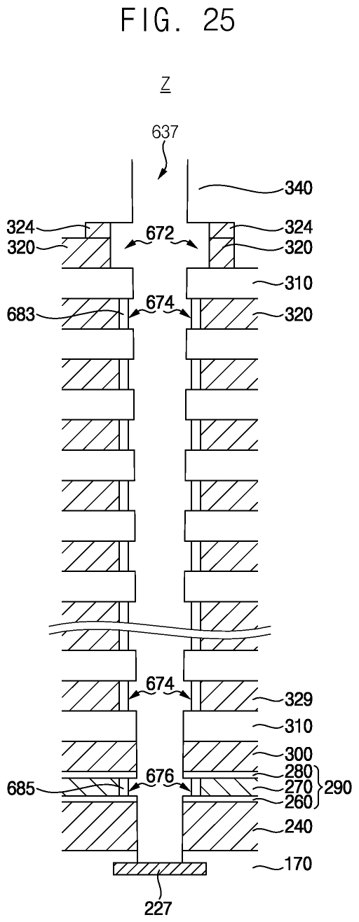

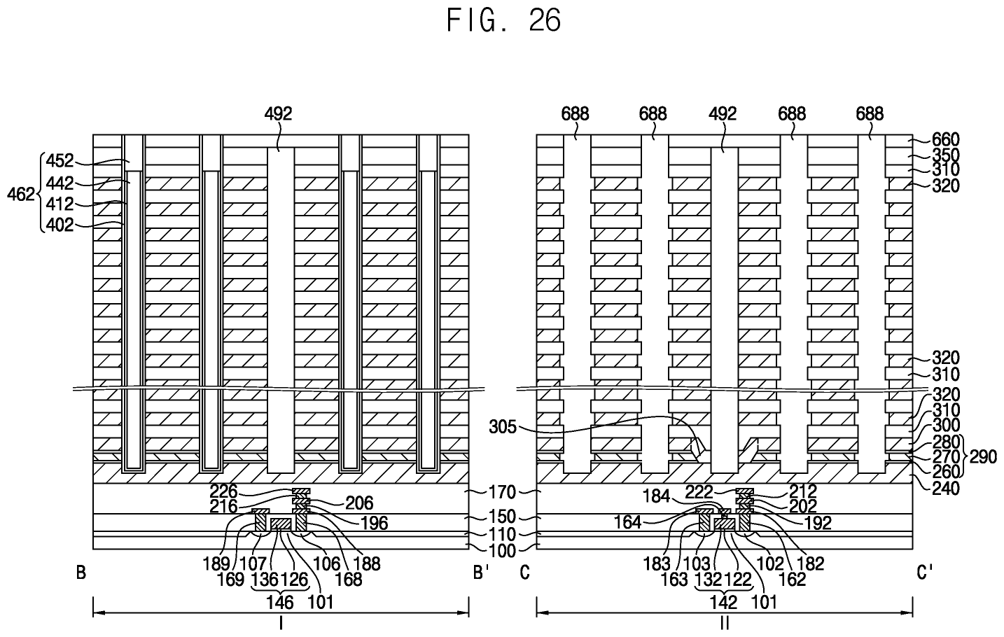

Referring to FIGS. 25 and 26, a second insulation layer may be formed on the CSP 240 and the tenth to thirteenth lower wirings 221, 223, 225 and 227 to fill the second hole 365, the fifth to eighth holes 631, 633, 635 and 637, and the third to eighth recesses 672, 674, 676, 673, 675 and 677, and may be planarized to form a support structure 688 in the second hole 365 and the sixth to eighth recesses 673, 675 and 677.

The second insulation layer may include an oxide, e.g., silicon oxide.

A wet etching process may be performed on the second insulation layer in the fifth to eighth holes 631, 633, 635 and 637, and second and third insulation patterns 683 and 685 may be formed in the fourth and fifth recesses 674 and 676, respectively. During the wet etching process, a portion of the second insulation layer in the third recess 672 exposed by each of the fifth to eighth holes 631, 633, 635 and 637 may be entirely removed, and thus no insulation pattern may remain in the third recess 672.

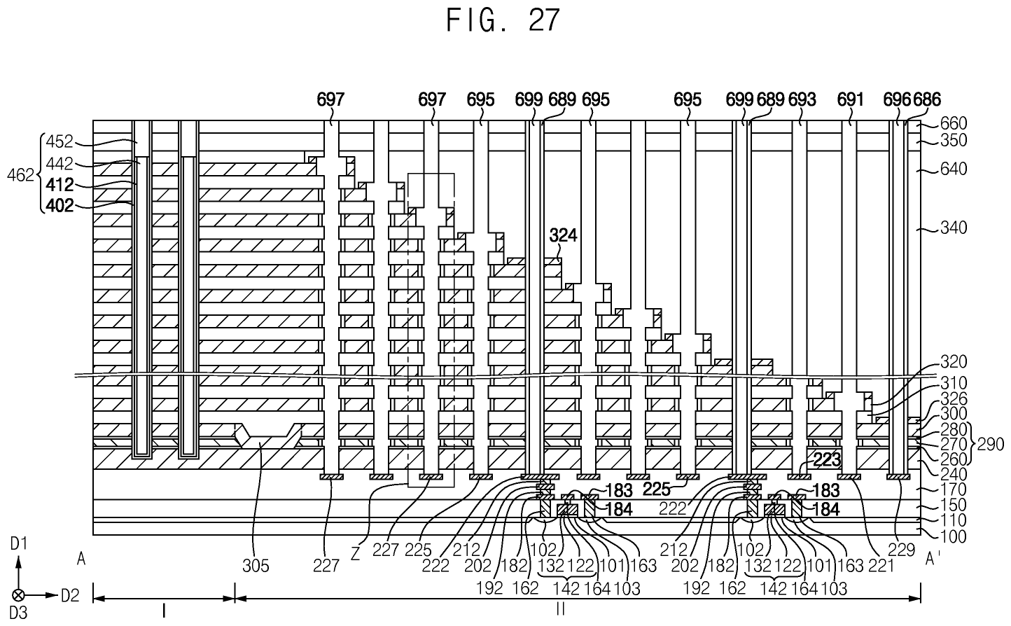

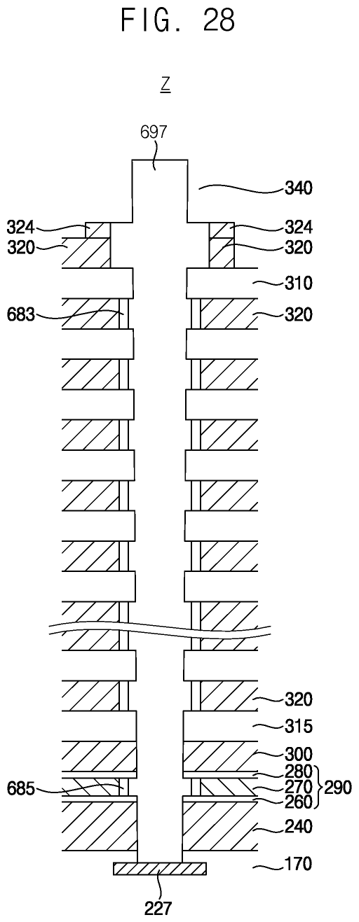

Referring to FIGS. 27 and 28, fifteenth to eighteenth sacrificial patterns 691, 693, 695 and 697 may be formed in the fifth to eighth holes 631, 633, 635 and 637, respectively, and the third to fifth recesses 672, 674 and 676 connected to each of the fifth to eighth holes 631, 633, 635 and 637 may be filled with a corresponding one of the fifteenth to eighteenth sacrificial patterns 691, 693, 695 and 697.

Each of the fifteenth to eighteenth sacrificial patterns 691, 693, 695 and 697 may include, e.g., polysilicon.

In example embodiments, the fifth insulating interlayer 660 may be patterned by an etching process to expose the thirteenth and fourteenth sacrificial patterns 640 and 652, and the exposed thirteenth and fourteenth sacrificial patterns 640 and 652 may be removed to form the ninth and tenth holes 639 and 650 exposing the upper surfaces of the fourteenth and eighth lower wirings 229 and 222, respectively, again.

Fourth and fifth insulation patterns 686 and 689 may be formed on sidewalls of the ninth and tenth holes 639 and 650, respectively, and nineteenth and twentieth sacrificial patterns 696 and 699 may be formed in the ninth and tenth holes 639 and 650, respectively. Each of the nineteenth and twentieth sacrificial patterns 696 and 699 may include, e.g., polysilicon.

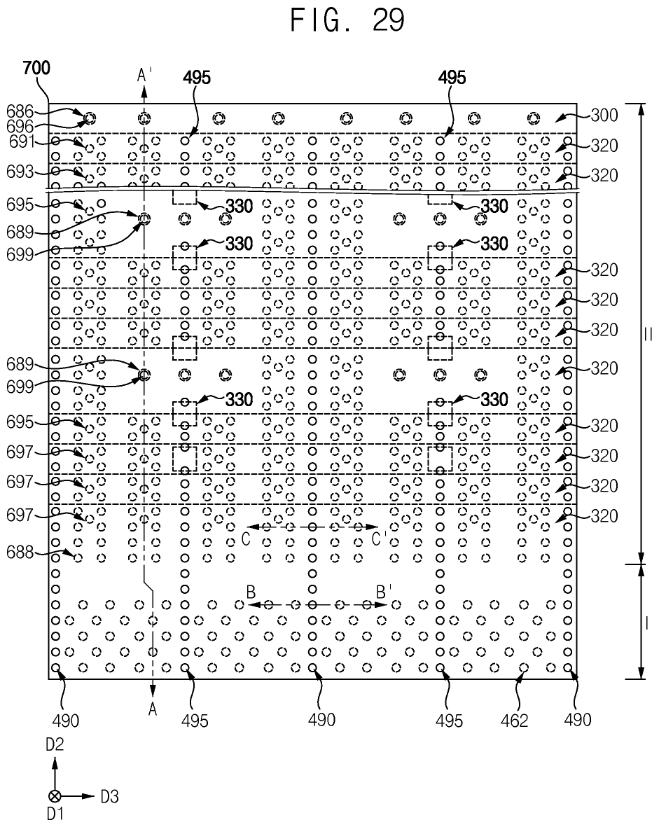

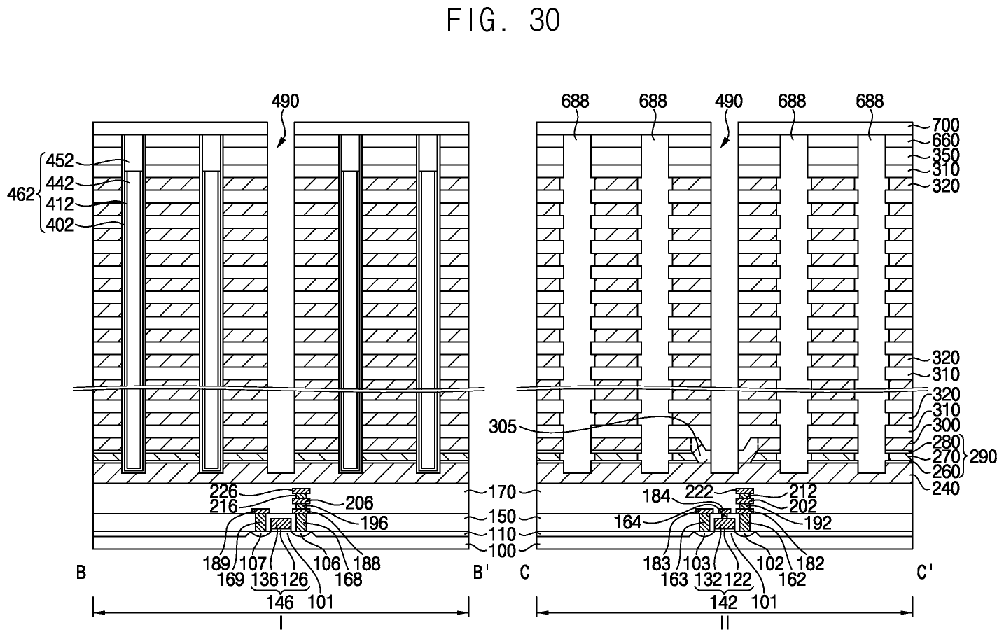

Referring to FIGS. 29 and 30, a sixth insulating interlayer 700 may be formed on the fifth insulating interlayer 660, the first memory channel structure 462, the support structure 688, the fifteenth to twentieth sacrificial patterns 691, 693, 695, 697, 696 and 699, and the fourth and fifth insulation patterns 686 and 689, the sixth insulating interlayer 700 may be patterned to expose the seventh and eighth sacrificial patterns 492 and 496, and the exposed seventh and eighth sacrificial patterns 492 and 496 may be removed to form the third and fourth holes 490 and 495 exposing the upper surface of the CSP 240 again.

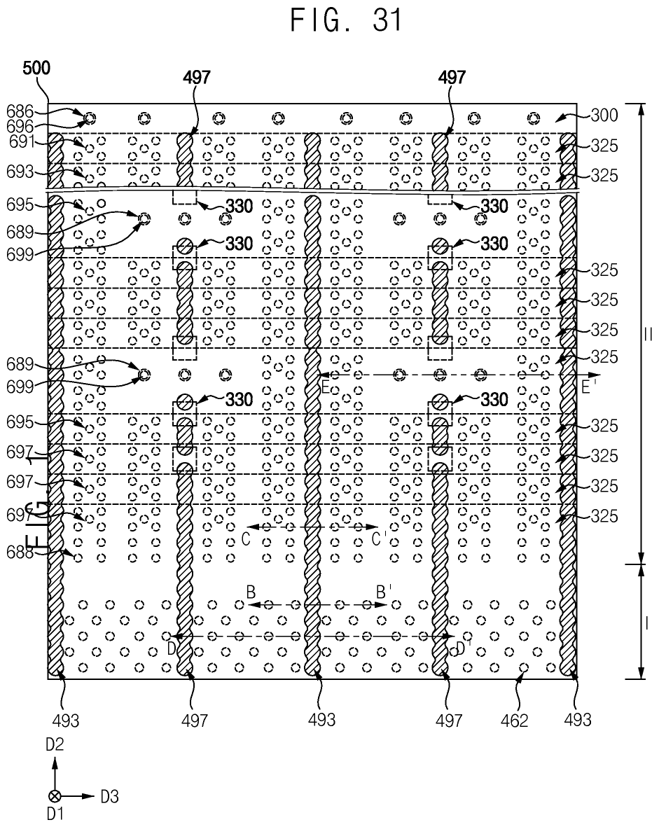

Referring to FIGS. 31 and 32, in example embodiments, a wet etching process may be performed to enlarge widths of the third and fourth holes 490 and 495, and thus, the third holes 490 neighboring in the second direction D2 may be connected to each other to form a third opening 493, and the fourth holes 495 neighboring in the second direction D2 may be connected to each other to form a fourth opening 497.

In example embodiments, the third opening 493 may extend in the second direction D2 on the first and second regions I and II of the substrate 100 to opposite end portions in the second direction D2 of the mold having a staircase shape, and a plurality of third openings 493 may be spaced apart from each other in the third direction D3. As the third opening 493 is formed, the first insulation layers 310 and the fourth sacrificial layers 320 included in the mold may be divided into first insulation patterns 315 and fourth sacrificial patterns 325, respectively.

In example embodiments, the fourth opening 497 may continuously extend in the second direction D2 on the first region I of the substrate 100, while a plurality of fourth openings 497 each of which may be formed by connecting the fourth holes 495 included in each of the fourth hole groups may be spaced apart from each other in the second direction D2 on the second region II of the substrate 100. The fourth openings 497 spaced apart from each other may be formed between ones of the third openings 493 neighboring in the second direction D2.

Unlike the third opening 493 extending in the second direction D2 to opposite end portions of the mold, a plurality of fourth openings 497 may be spaced apart from each other in the second direction D2, and thus the mold may not be entirely divided in the third direction D3 by the fourth openings 497. In example embodiments, each of portions of the mold between neighboring ones of the fourth openings 497 in the second direction D2 may at least partially overlap the first division pattern 330 in the first direction D1. The plurality of fourth openings 497 may include multiple spaced-apart segments extending in the second direction D2, where a fourth opening 497 segment may terminate at and overlap a first division pattern 330.

In example embodiments, each of the fourth openings 497 may continuously extend in the second direction D2 on the first region I of the substrate 100, and may also continuously extend in the second direction D2 on a portion of the second region II adjacent to the first region I of the substrate 100.

Even though the mold may be divided into a plurality of parts, each of which may extend in the second direction D2, spaced apart from each other in the third direction D3 by the wet etching process for forming the third and fourth openings 493 and 497, the mold may not lean or collapse by the support structures 688 and the first memory channel structures 462.

In example embodiments, the wet etching process may be performed until the upper surface of the CSP 240 is exposed by the third and fourth openings 493 and 497, and further the third and fourth openings 493 and 497 may extend through an upper portion of the CSP 240.

A twenty-first sacrificial pattern may be formed in a lower portion of each of the third and fourth openings 493 and 497, a spacer layer may be formed on an upper surface of the twenty-first sacrificial pattern, sidewalls of the third and fourth openings 493 and 497, and an upper surface of the sixth insulating interlayer 700, and a portion of the spacer layer on the upper surface of the twenty-first sacrificial pattern may be removed by an anisotropic etching process.

In example embodiments, the upper surface of the twenty-first sacrificial pattern may be higher than an upper surface of the sacrificial layer structure 290 and lower than an upper surface of the support layer 300. Thus, the spacer 500 may cover sidewalls of the first insulation patterns 315 and the fourth sacrificial patterns 325 exposed by the third and fourth openings 493 and 497. The spacer 500 may include, e.g., undoped polysilicon.

The twenty-first sacrificial pattern may be removed.

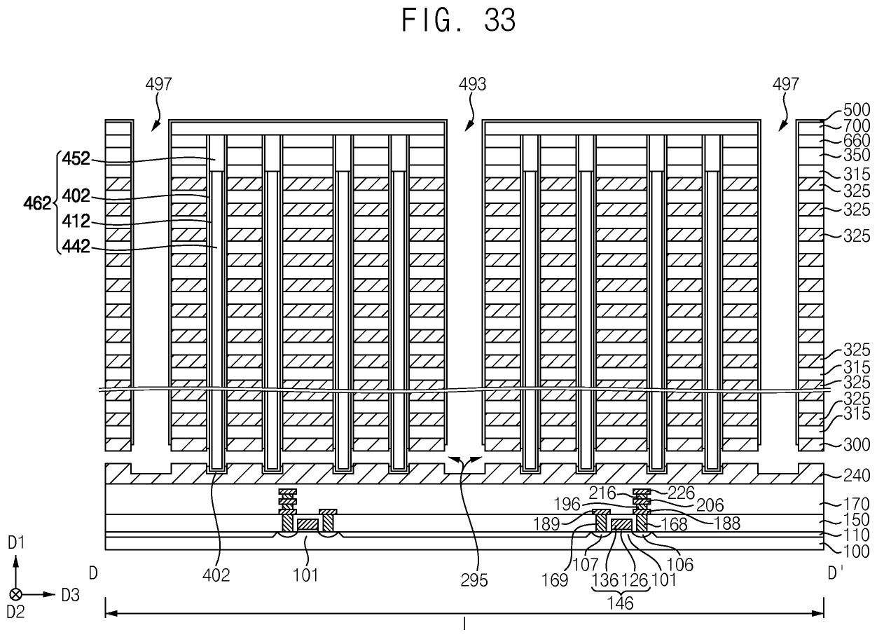

Referring to FIG. 33, the sacrificial layer structure 290 may be removed through the third and fourth openings 493 and 497 by, e.g., a wet etching process to form a first gap 295.

The wet etching process may be performed using, e.g., HF and/or H₃PO₄. In example embodiments, each of the third and fourth openings 493 and 497 may extend through the support pattern 305 instead of the support layer 300 and the sacrificial layer structure 290 on the second region II of the substrate 100, and thus the sacrificial layer structure 290 may not be removed by the wet etching process on the second region II of the substrate 100.

As the first gap 295 is formed, a lower surface of the support layer 300 and the upper surface of the CSP 240 may be exposed. Additionally, a portion of a sidewall of the first charge storage structure 402 on the first region I of the substrate 100 may be exposed by the first gap 295, and the exposed portion of the sidewall of the first charge storage structure 402 may also be removed during the wet etching process. Thus, the first charge storage structure 402 may be divided into an upper portion extending through the mold and covering most of a portion of an outer sidewall of the first channel 412, and a lower portion covering a lower surface of the first channel 412 and on the CSP 240. A portion of the first channel 412 can be exposed by removal of the portion of the first charge storage structure 402.

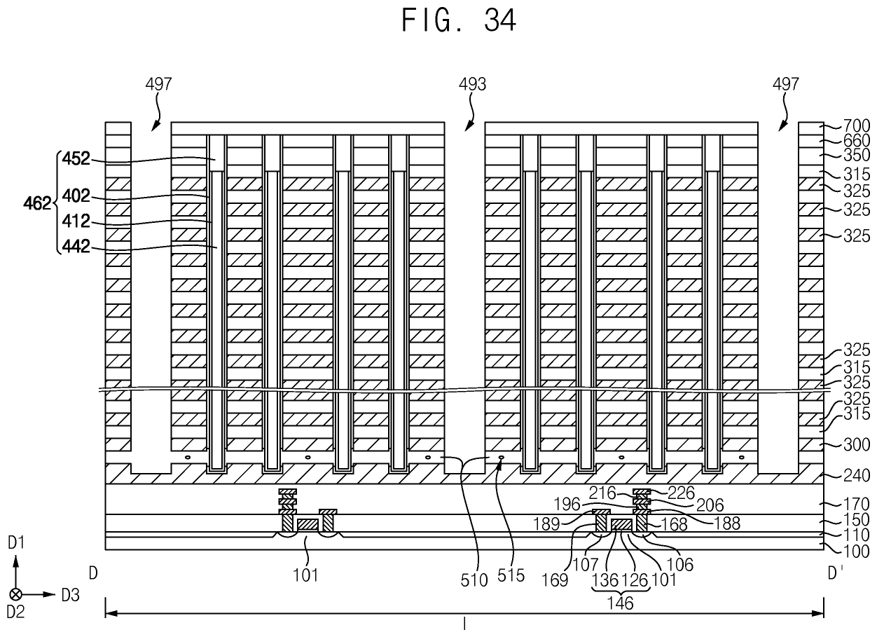

Referring to FIG. 34, the spacer 500 may be removed, a channel connection layer may be formed in the sidewalls of the third and fourth openings 493 and 497 and the first gap 295, and portions of the channel connection layer in the third and fourth openings 493 and 497 may be removed by, e.g., an etch back process to form a channel connection pattern 510 in the first gap 295.

As the channel connection pattern 510 is formed, the first channels 412 between neighboring ones of the third and fourth openings 493 and 497 in the third direction D3 may be connected with each other. Where the channel connection pattern 510 is a conductive material, an electrical connection can be formed between two or more of the first channels 412.

In example embodiments, an air gap 515 may be formed in the channel connection pattern 510, where formation of the channel connection pattern 510 may pinch off portions of the first gap 295.

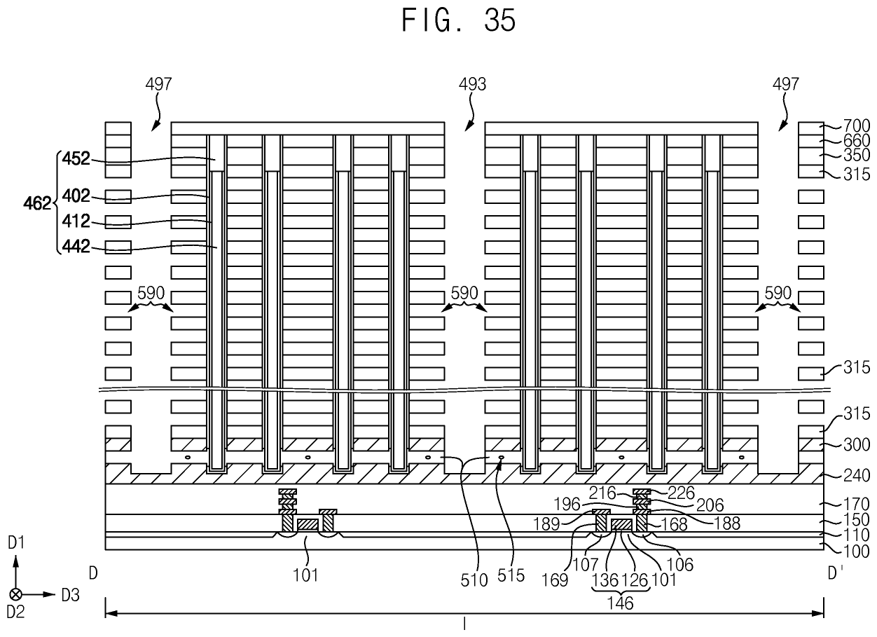

Referring to FIGS. 34 and 35, the fourth sacrificial patterns 325 and the second insulation pad 324 exposed by the third and fourth openings 493 and 497 may be removed to form a second gap 590 between neighboring ones of the first insulation patterns 315 in the first direction D1, and a portion of an outer sidewall of the first charge storage structure 402 included in the first memory channel structure 462, a portion of a sidewall of the support structure 688, and portions of sidewalls of the fifteenth to eighteenth sacrificial patterns 691, 693, 695 and 697 may be exposed by the second gap 590.

In example embodiments, a wet etching process may be performed using an etching solution, e.g., H₃PO₄ or H₂SO₄ to remove the fourth sacrificial patterns 325.

The wet etching process may be performed through the third and fourth openings 493 and 497, and a portion of the fourth sacrificial pattern 325 between neighboring ones of the third and fourth openings 493 and 497 may be entirely removed by an etching solution provided from the third and fourth openings 493 and 497 in opposite ways. However, at an area where the fourth opening 497 is not formed between the third openings 493 on the second region II of the substrate 100, the etching solution may be provided from the third opening 493 in one way, so that the fourth sacrificial pattern 325 may not be entirely removed but partially remain, which may be referred to as a seventh insulation pattern 327. Additionally, a portion of the first insulation pattern 315 overlapping the seventh insulation pattern 327 in the first direction D1 may be referred to as a sixth insulation pattern 317. The sixth and seventh insulation patterns 317 and 327 alternately and repeatedly stacked in the first direction D1 may form an insulation pattern structure 600 (see e.g., FIG. 36). The sixth insulation pattern 317 may include an oxide, e.g., silicon oxide, and the seventh insulation pattern 327 may include a nitride, e.g., silicon nitride.

In example embodiments, the insulation pattern structure 600 may extend through a portion of the mold on the second region II of the substrate 100, and may have a shape of, e.g., a rectangle, an ellipse, a circle, etc., in a plan view. In example embodiments, the insulation pattern structure 600 may extend through the second step having a relatively large length in the second direction D2 in each mold.

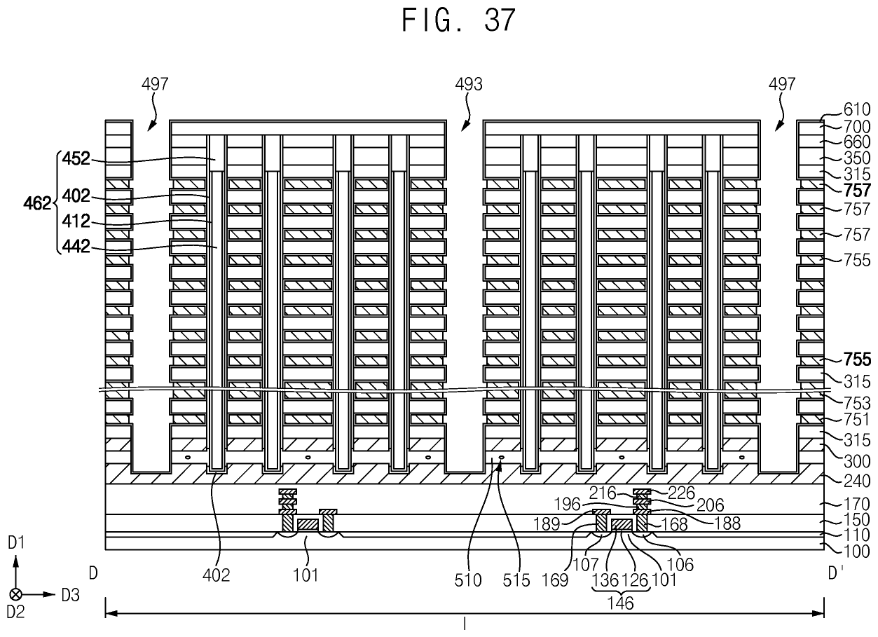

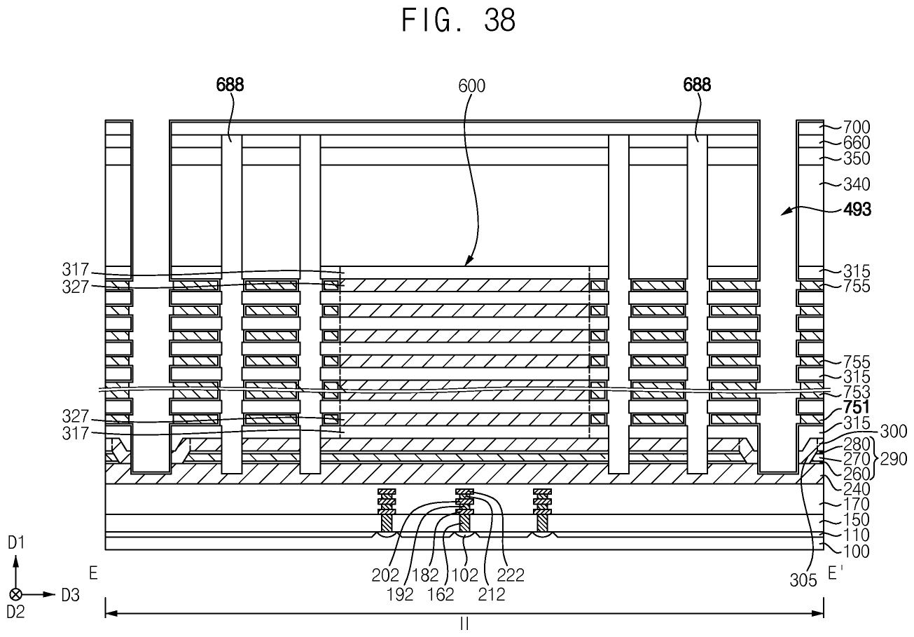

Referring to FIGS. 37 and 38, a second blocking layer 610 may be formed on the outer sidewall of the first charge storage structure 402, the sidewall of the support structure 688 and the sidewalls of the fifteenth to eighteenth sacrificial patterns 691, 693, 695 and 697 exposed by the second gaps 590, inner walls of the second gaps 590, surfaces of the first insulation patterns 315, sidewalls of the fourth to sixth insulating interlayers 350, 660 and 700, and an upper surface of the sixth insulating interlayer 700, and a gate electrode layer may be formed on the second blocking layer 610.

In example embodiments, the gate electrode layer may include a gate barrier layer and a gate conductive layer that are sequentially stacked. The gate barrier layer may include, e.g., a metal nitride, and the gate conductive layer may include, e.g., a metal.

In example embodiments, the gate electrode layer may be partially removed to form a gate electrode in each of the second gaps 590. In example embodiments, the gate electrode layer may be partially removed by a wet etching process. As a result, the fourth sacrificial pattern 325 in the mold including the step layer of the first insulation pattern 315 and the fourth sacrificial pattern 325 may be replaced with the gate electrode and the second blocking layer 610 covering lower and upper surfaces of the gate electrode.

In example embodiments, the gate electrode may extend in the second direction D2, and a plurality of gate electrodes may be spaced apart from each other at a plurality of levels, respectively, to form a preliminary gate electrode structure. The preliminary gate electrode structure may have a staircase shape including the gate electrodes as respective steps. An end portion in the second direction D2 of each of the gate electrodes that is not overlapped by upper gate electrodes in the first direction D1, where the step of the step layer having a relatively large thickness may be referred to as a pad. The preliminary gate electrode structure may include first pads having a relatively small length in the second direction D2 and second pads having a relatively large length in the second direction D2. The numbers of the first and second pads are not limited.

Additionally, a plurality of preliminary gate electrode structures may be formed in the third direction D3, which may be spaced apart from each other by the third openings 493. As illustrated above, the fourth opening 497 may not continuously extend in the second direction D2 to opposite end portions of the mold, and thus the preliminary gate electrode structure may not be entirely divided by the fourth opening 497. However, a lowermost one of the gate electrodes included in the preliminary gate electrode structure may be divided by the fourth openings 497, the first division pattern 330 and the insulation pattern structure 600 in the third direction D3.

The preliminary gate electrode structure may include first to fourth gate electrodes 751, 753, 755 and 757 sequentially stacked in the first direction D1. In example embodiments, the first gate electrode may be formed at a lowermost level, and may serve as a ground selection line (GSL). The second gate electrode 753 may be formed at one or a plurality of levels over the first gate electrode 751, and may serve as a GIDL gate electrode. The third gate electrodes 755 may be formed at a plurality of levels, respectively, over the second gate electrode 753, and may serve as word lines, respectively. The fourth gate electrode 757 may be formed at one or a plurality of levels over the third gate electrode 755, and may serve as the GIDL gate electrode.

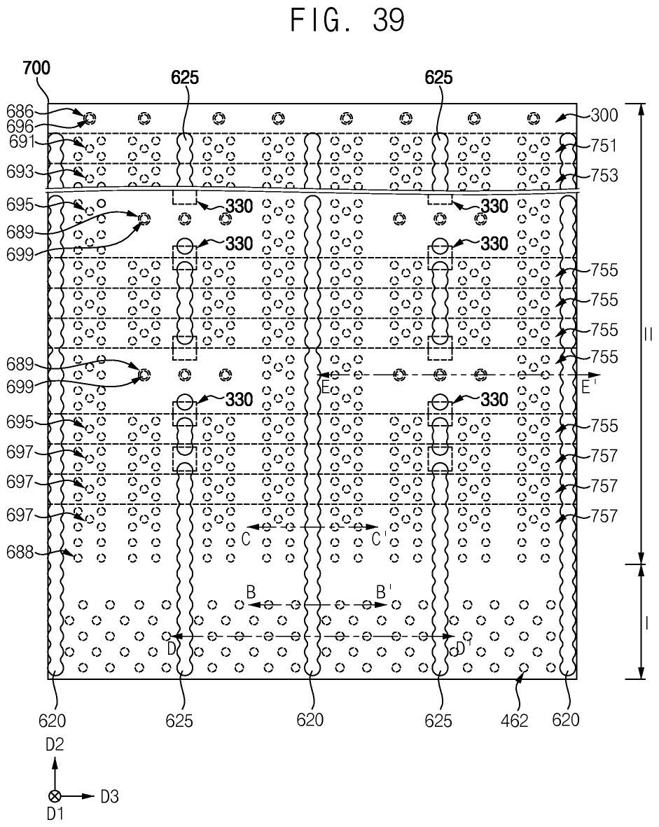

Referring to FIGS. 39 to 41, a second division layer may be formed on the second blocking layer 610 to fill the third and fourth openings 493 and 497, and the second division layer and the second blocking layer 610 may be planarized until the upper surface of the sixth insulating interlayer 700 is exposed.

Thus, the second blocking layer 610 may be transformed into a second blocking pattern 615, and second and third division patterns 620 and 625 may be formed in the third and fourth openings 493 and 497, respectively.

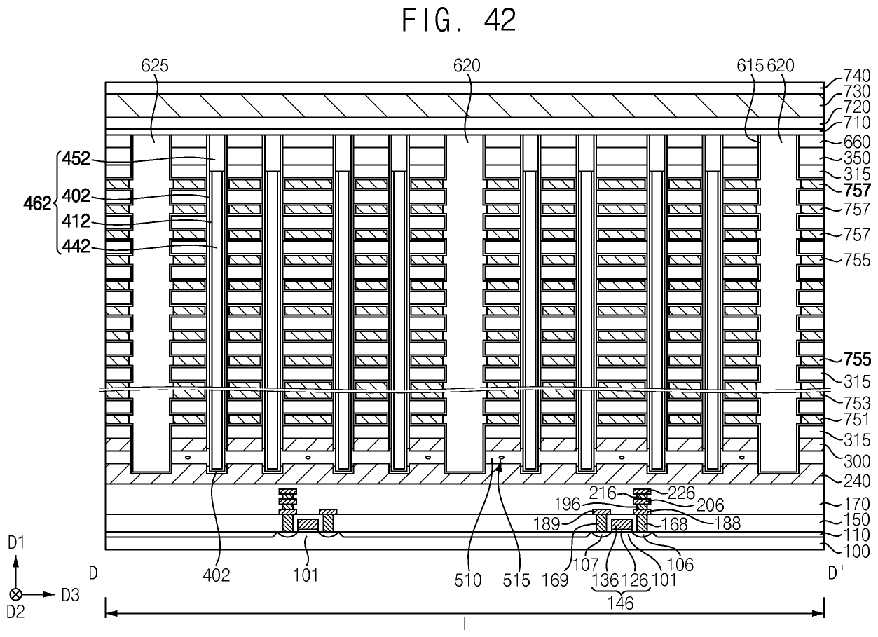

Referring to FIG. 42, the sixth insulating interlayer 700 may be planarized until the upper surface of the fifth insulating interlayer 660 is exposed, and during the planarization process, upper portions of the second and third division patterns 620 and 625 may also be removed.

Thus, upper surface of the first memory channel structure 462, the support structure 688, the fifteenth to twentieth sacrificial patterns 691, 693, 695, 697, 696 and 699, and the fourth and fifth insulation patterns 686 and 689 may be exposed.

A seventh insulating interlayer 710, an etch stop layer 720, a fifth gate electrode layer 730 and a mask layer 740 may be sequentially stacked on the fifth insulating interlayer 660, the first memory channel structure 462, the support structure 688, the fifteenth to twentieth sacrificial patterns 691, 693, 695, 697, 696 and 699, and the fourth and fifth insulation patterns 686 and 689.

The mask layer 740 may include an oxide, e.g., silicon oxide.

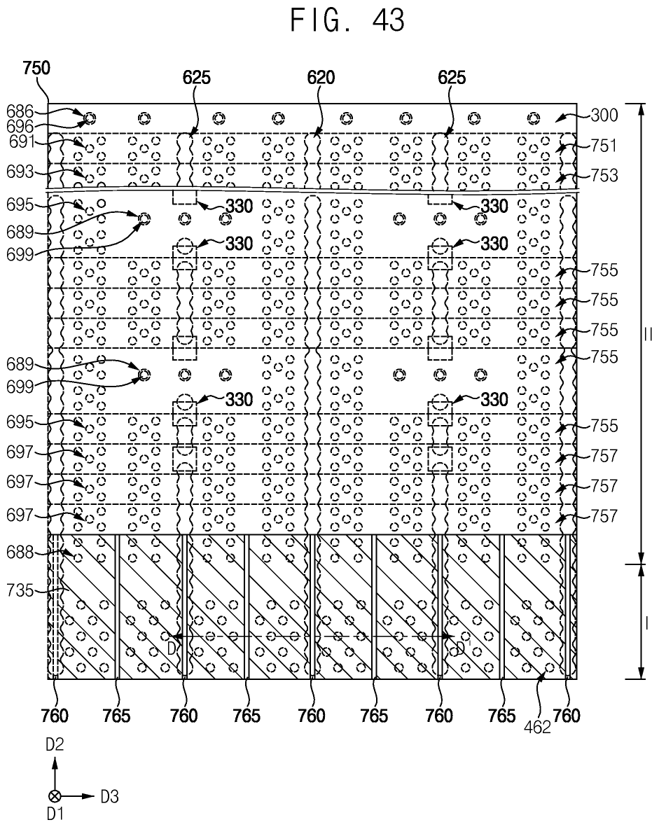

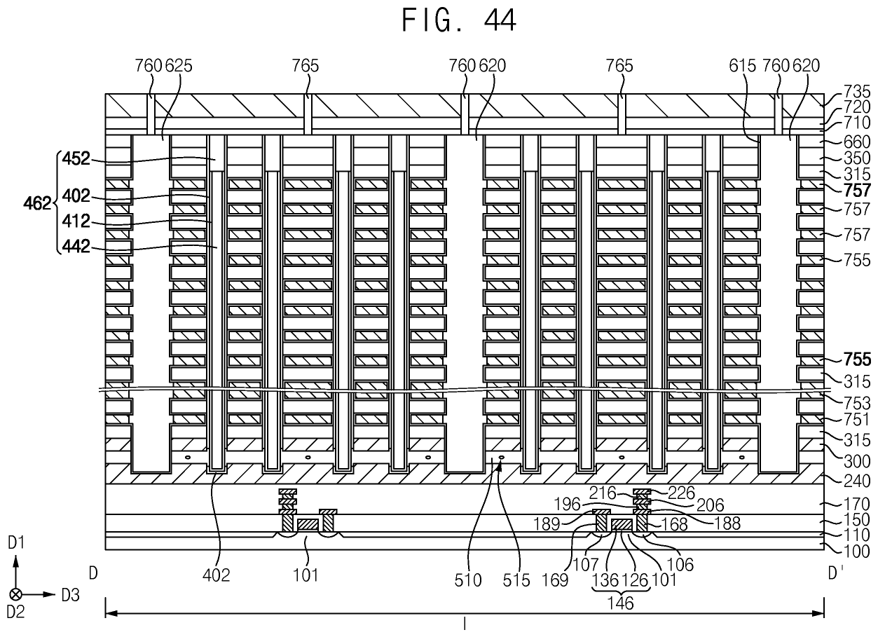

Referring to FIGS. 43 and 44, portions of the etch stop layer 720, the fifth gate electrode layer 730 and the mask layer 740 on the second region II of the substrate 100 except for a portion of the second region II adjacent to the first region I of the substrate 100 may be removed, the mask layer 740 may be patterned to form a mask, and the fifth gate electrode layer 730, the etch stop layer 720 and the seventh insulating interlayer 710 may be etched using the mask as an etching mask to form fifth and sixth openings.

In example embodiments, the fifth opening may expose an upper surface of each of the second and third division patterns 620 and 625, and the sixth opening may expose an upper surface of a portion of the fifth insulating interlayer 660 between the second and third division patterns 620 and 625.

Fourth and fifth division patterns 760 and 765 may be formed in the fifth and sixth openings, respectively, the mask may be removed, and an eighth insulating interlayer 750 may be formed on the seventh insulating interlayer 710 on the second region II of the substrate 100.

Each of the fourth and fifth division patterns 760 and 765 may extend in the second direction D2 on the first region I of the substrate 100 and the portion of the second region II of the substrate adjacent to the first region I of the substrate 100. Additionally, a plurality of fourth division patterns 760 may be spaced apart from each other in the third direction D3, and may contact upper surfaces of the second and third division patterns 620 and 625, respectively. The fifth division pattern 765 may be formed between neighboring ones of the fourth division patterns 760 in the third direction D3.

Thus, the fifth gate electrode layer 730 may be divided into a plurality of fifth gate electrodes 735, each of which may extend in the second direction D2, spaced apart from each other in the third direction D3 by the fourth and fifth division patterns 760 and 765, and each of the fifth gate electrodes 735 may serve as a string selection line (SSL).

The fifth gate electrode 735 and the preliminary gate electrode structure including the first to fourth gate electrodes 751, 753, 755 and 757 may form a gate electrode structure.

In example embodiments, a length in the second direction D2 of the fifth gate electrode 735 may be less than a length in the second direction D2 of an uppermost one of the fourth gate electrodes 757. Thus, a pad at an end portion in the second direction D2 of the uppermost one of the fourth gate electrodes 757 may not be overlapped by the fifth gate electrode 735 in the first direction D1, and the gate electrode structure may have a staircase shape.

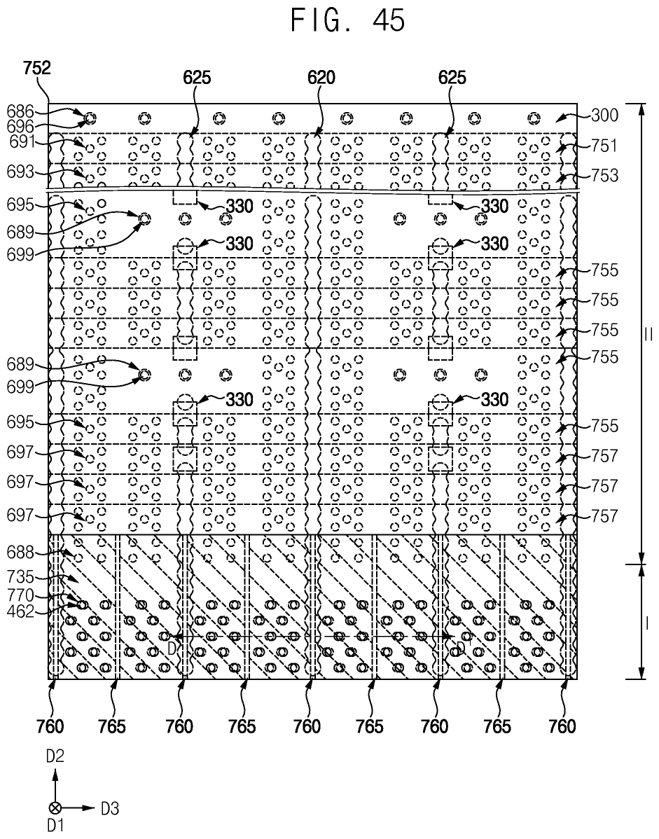

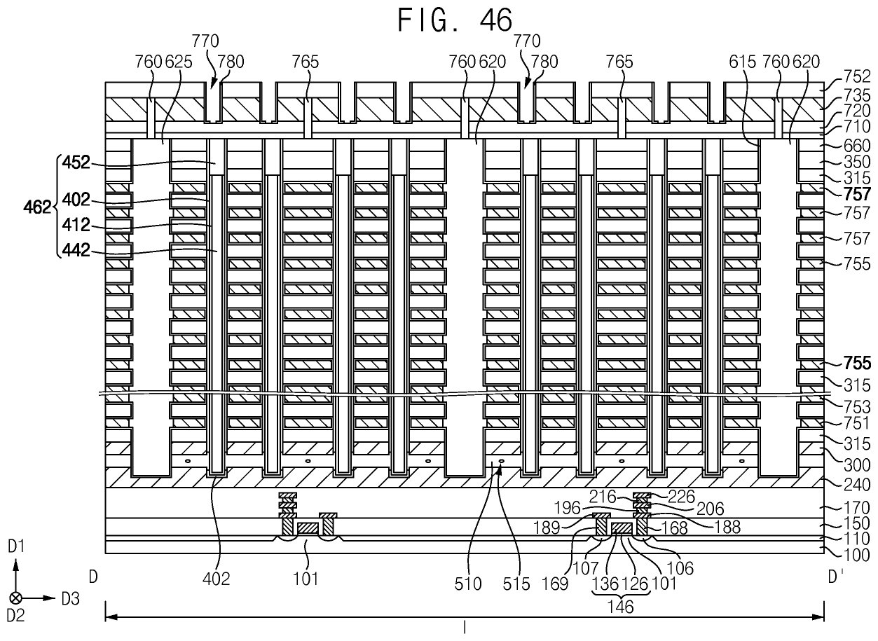

Referring to FIGS. 45 and 46, a ninth insulating interlayer 752 may be formed on the fifth gate electrode 735, the fourth and fifth division patterns 760 and 765 and the eighth insulating interlayer 750, and an eleventh hole 770 may be formed through the ninth insulating interlayer 752 and the fifth gate electrode 735 to expose an upper surface of the etch stop layer 720.

In example embodiments, a plurality of eleventh holes 770 may be spaced apart from each other in the second and third directions D2 and D3, and each of the plurality of eleventh holes 770 may partially overlap a corresponding one of the first memory channel structures 462 in the first direction D1, such that the eleventh holes 770 may not be colinear with the underlying first memory channel structures 462.

A second charge storage structure layer may be formed on a sidewall and a bottom of the eleventh hole 770 and an upper surface of the ninth insulating interlayer 752, and an etch back process may be performed on the second charge storage structure layer to form a second charge storage structure 780 on the sidewall and an edge portion of the bottom of the eleventh hole 770. The second charge storage structure 780 may include a third blocking pattern, a second charge storage pattern and a second tunnel insulation pattern sequentially stacked on the sidewall of the eleventh hole 770.

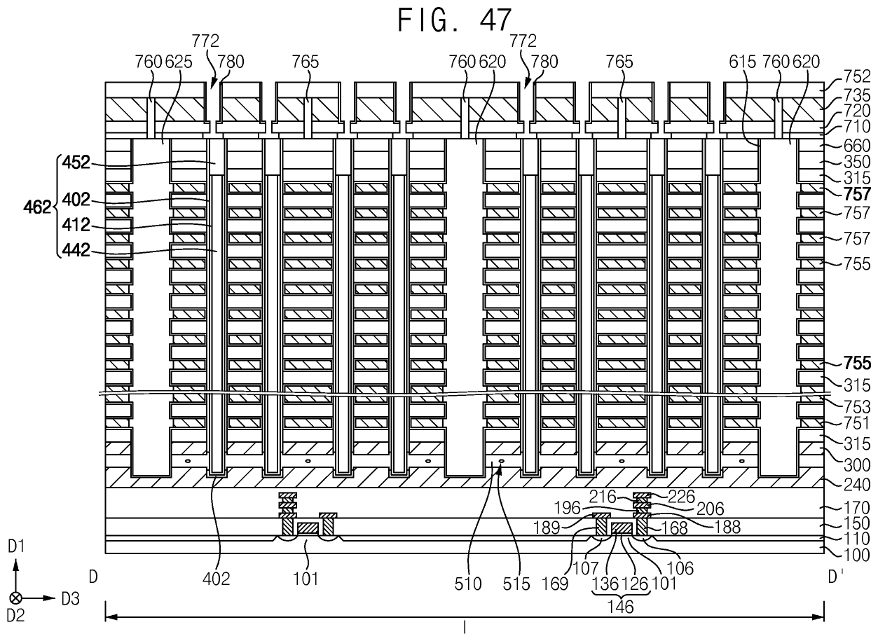

Referring to FIG. 47, the portion of the etch stop layer 720 exposed by the second charge storage structure 780 and a portion of the seventh insulating interlayer 710 thereunder may be removed to enlarge the eleventh hole 770 in the first direction D1, and a portion of the seventh insulating interlayer 710 adjacent to the enlarged eleventh hole 770 may be additionally removed to enlarge the eleventh hole 770 in the horizontal direction. Thus, a twelfth hole 772 at least partially exposing an upper surface of the first memory channel structure 462 may be formed.

The twelfth hole 772 may also expose an upper surface of a portion of the fifth insulating interlayer 660 adjacent to the first memory channel structure 462.

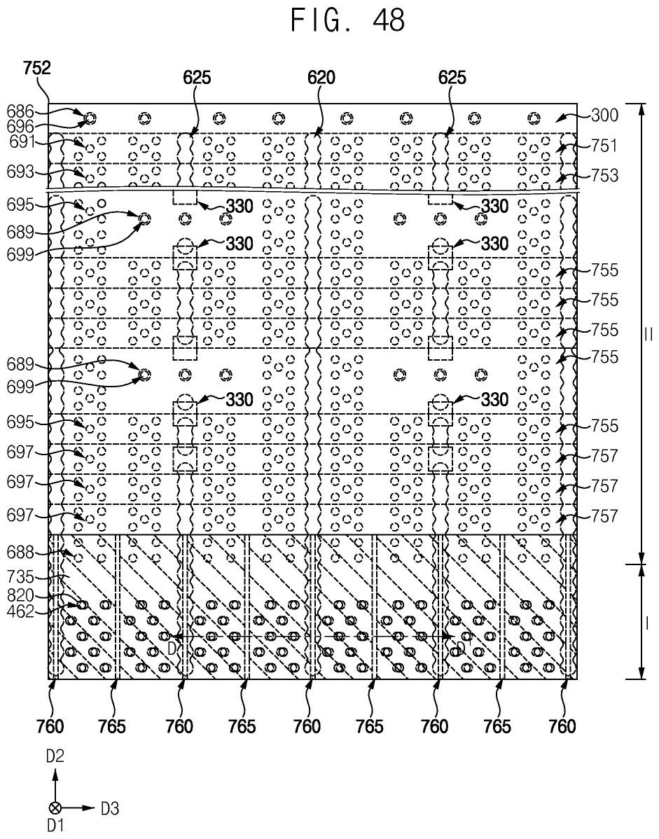

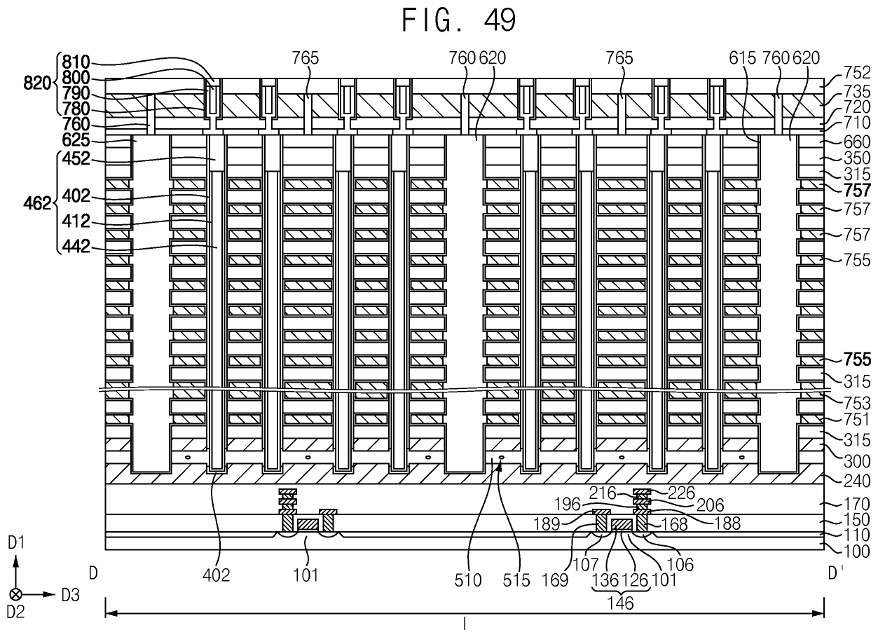

Referring to FIGS. 48 and 49, a second channel 790, a second filling pattern 800 and a second capping pattern 810 may be formed in the twelfth hole 772.

In example embodiments, the second channel 790 may be formed in a lower portion of the twelfth hole 772 surrounded by the seventh insulating interlayer 710 and the etch stop layer 720, and on an inner sidewall of the second charge storage structure 780 on a sidewall of the twelfth hole 772 surrounded by the fifth gate electrode 735 and the ninth insulating interlayer 752. The second filling pattern 800 may fill a space surrounded by the second channel 790. The second capping pattern 810 may be formed on the second channel 790 and the second filling pattern 800 in an upper portion of the twelfth hole 772, and may be surrounded by the second charge storage structure 780.

The second charge storage structure 780, the second channel 790, the second filling pattern 800 and the second capping pattern 810 may collectively form a second memory channel structure 820, and may be connected to the first memory channel structure 462.

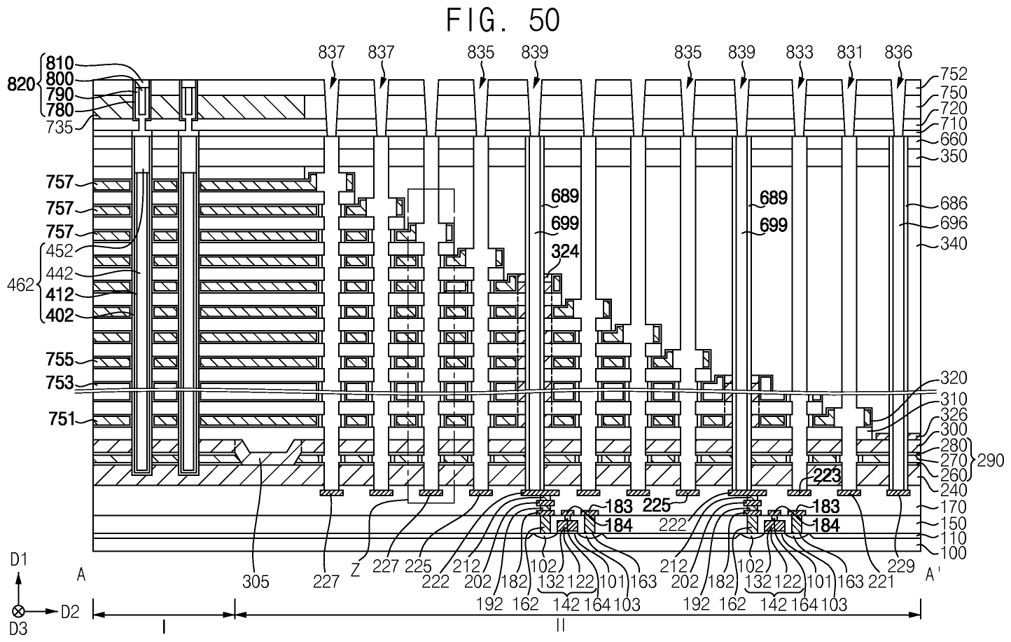

Referring to FIG. 50, thirteenth to eighteenth holes 831, 833, 835, 837, 836 and 839 may be formed through the seventh to ninth insulating interlayers 710, 750 and 752 and the etch stop layer 720 to expose the fifteenth to twentieth sacrificial patterns 691, 693, 695, 697, 696 and 699, respectively.

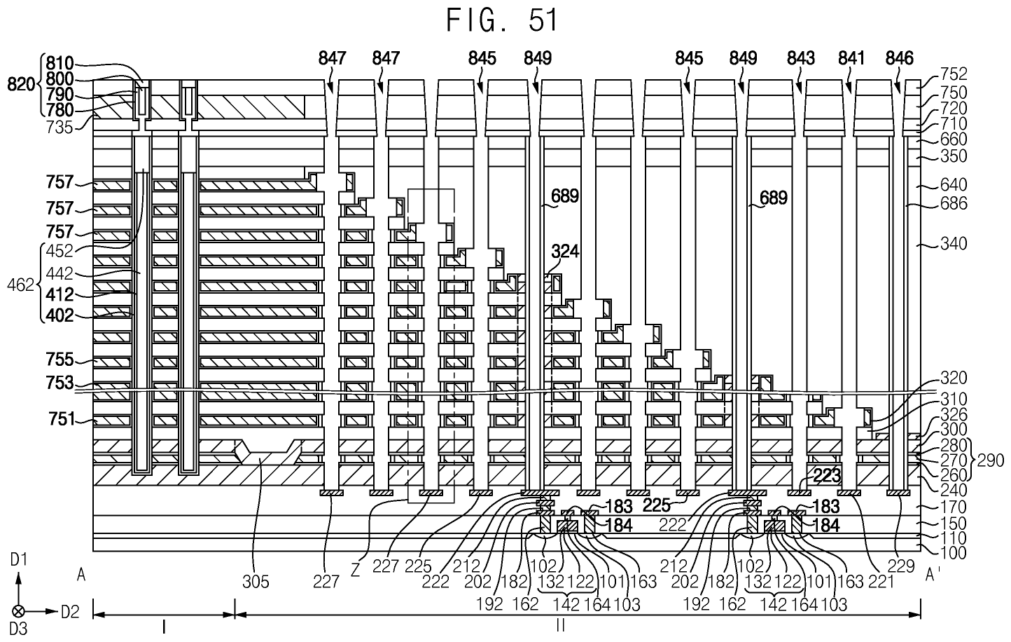

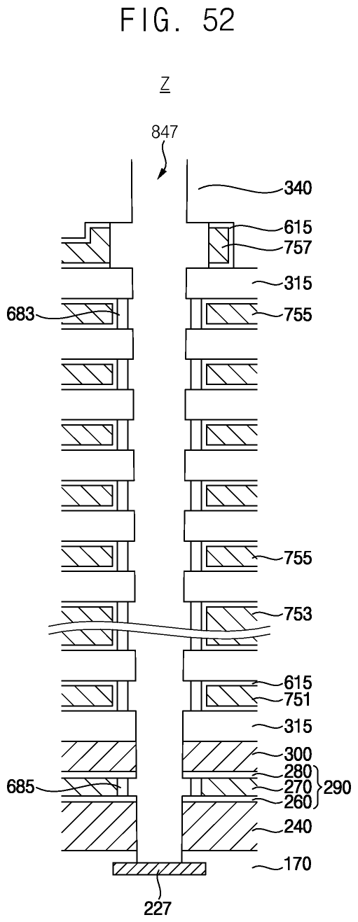

Referring to FIGS. 51 and 52, the exposed fifteenth to twentieth sacrificial patterns 691, 693, 695, 697, 696 and 699 may be removed by an etching process to form nineteenth to twenty-fourth holes 841, 843, 845, 847, 846 and 849, respectively, and thus upper surfaces of the tenth to fourteenth lower wirings 221, 223, 225, 227 and 229 and the eighth lower wiring 222 may be exposed.

During the etching process, a portion of the second blocking pattern 615 not covered by the second and third insulation patterns 683 and 685 in each of the nineteenth to twenty-second holes 841, 843, 845 and 847 may also be removed, and thus a sidewall of an uppermost one of the gate electrodes in each of the nineteenth to twenty-second holes 841, 843, 845 and 847 may be exposed.

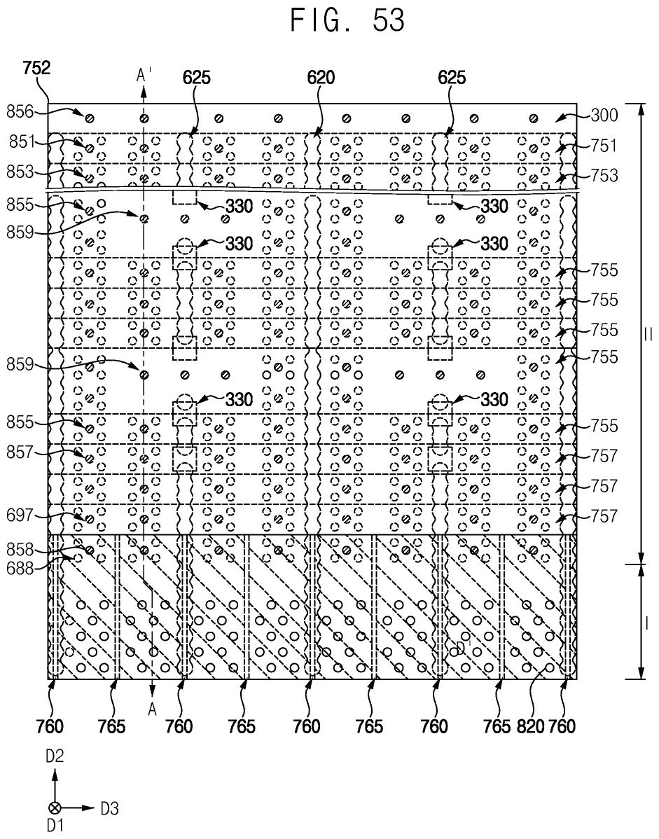

Referring to FIGS. 53 to 55, first to sixth upper contact plugs 851, 853, 855, 857, 856 and 859 may be formed in the nineteenth to twenty-fourth holes 841, 843, 845, 847, 846 and 849, respectively.

Additionally, a seventh upper contact plug 858 may be formed through the ninth insulating interlayer 752 to contact an upper surface of the fifth gate electrode 735.

Referring to FIGS. 1 to 7, tenth to twelfth insulating interlayers 860, 880 and 900 may be sequentially stacked on the ninth insulating interlayer 752 and the first to seventh upper contact plugs 851, 853, 855, 857, 856, 859 and 858, and an eighth upper contact plugs 870, upper vias 890 and upper wirings 910 may be formed through the tenth to twelfth insulating interlayers 860, 880 and 900.

In some embodiments, additional insulating interlayers, additional upper vias and additional upper wirings may be further formed on the twelfth insulating interlayer 900 and the upper wirings 910.

As illustrated above, the first to fourth upper contact plugs 851, 853, 855 and 857 may be formed by the same process, which may simplify the method of manufacturing the semiconductor device and reduce the cost of the method.

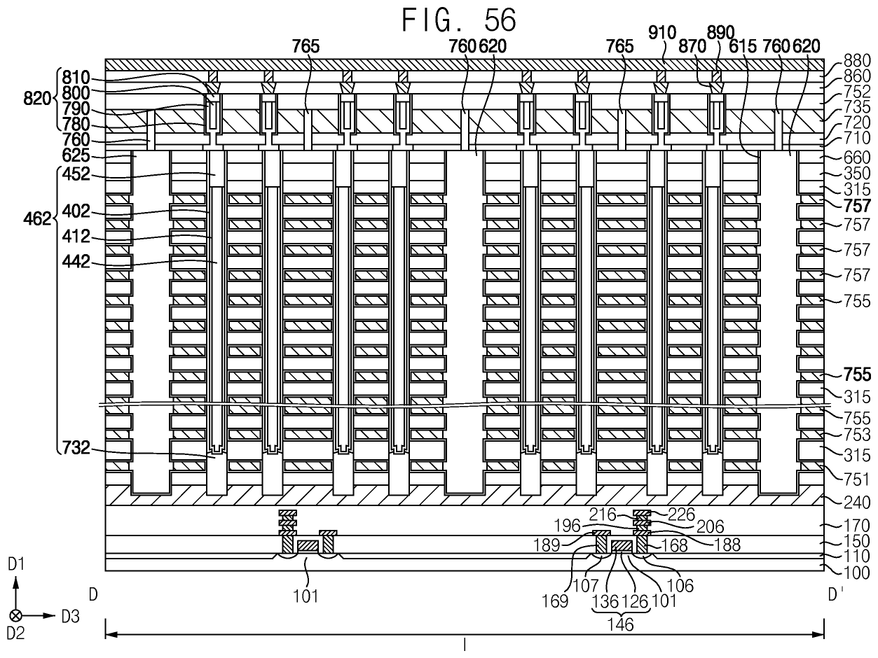

FIG. 56 is a cross-sectional view illustrating a semiconductor device in accordance with example embodiments, which may correspond to FIG. 6. The semiconductor device may be substantially the same as or similar to the semiconductor device illustrated in FIGS. 1 to 7, except for the first memory channel structure 462, the channel connection pattern 510, the support layer 300 and the support pattern 305.

Referring to FIG. 56, the first memory channel structure 462 may further include a semiconductor pattern 732 on the substrate 100, and the first charge storage structure 402, the first channel 412, the first filling pattern 442 and the first capping pattern 452 may be formed on the semiconductor pattern 732.

The semiconductor pattern 732 may include, for example, single crystalline silicon or polysilicon. In an example embodiment, an upper surface of the semiconductor pattern 732 may be located at a height between heights of lower and upper surfaces of the first insulation pattern 315 that may be disposed between the first and second gate electrodes 751 and 753. The first charge storage structure 402 may have a cup-like shape of which a central lower surface is opened on the upper surface of the semiconductor pattern 732, and may contact an edge upper surface of the semiconductor pattern 732. The first channel 412 may have a cup-like shape, and may contact a central upper surface of the semiconductor pattern 732. Thus, the first channel 412 may be electrically connected to the CSP 240 through the semiconductor pattern 732.

In example embodiments, the channel connection pattern 510, the support layer 300 and the support pattern 305 may not be formed between the CSP 240 and the first gate electrode 751. In an example embodiment, ones of the first insulation patterns 315 between the first and second gate electrodes 751 and 753 may have a greater thickness than those of the other upper ones the first insulation patterns 315. The first insulation pattern 315 may be between each of portions of a sidewall of the first contact plug 851 facing the first and second gate electrodes 751, 753, respectively, and a corresponding one of the first and second gate electrodes.

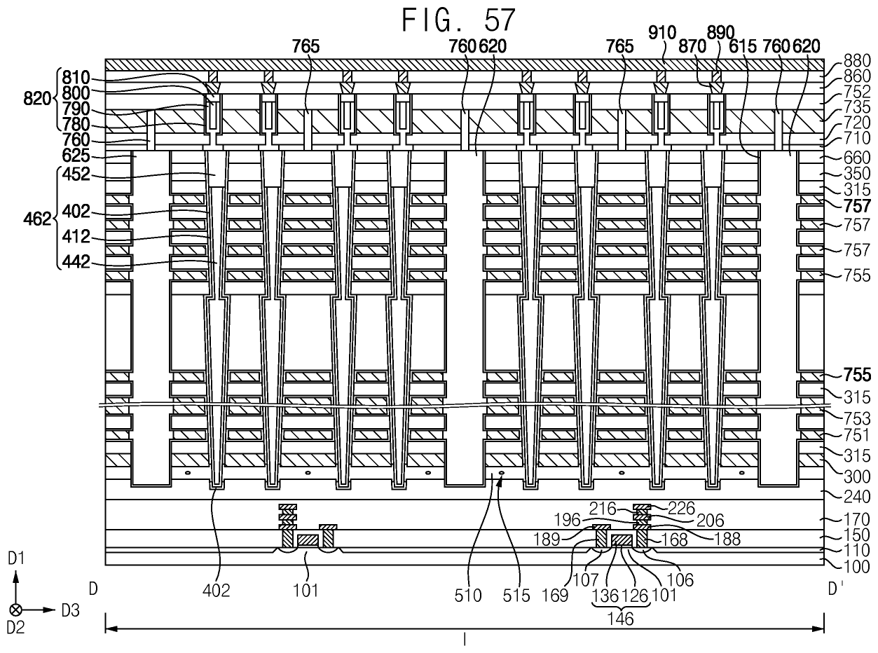

FIG. 57 is a cross-sectional view illustrating a semiconductor device in accordance with example embodiments, which may correspond to FIG. 6. This semiconductor device may be substantially the same as or similar to that of FIGS. 1 to 7, except for the shape of the first memory channel structure 462.

Referring to FIG. 57, the first memory channel structure 462 included in the semiconductor device may include sequentially stacked lower and upper portions, and each of the lower and upper portions may have a width gradually decreasing from a top toward a bottom thereof. In example embodiments, an upper surface of the lower portion of the first memory channel structure 462 may have a width greater than a width of a lower surface of the upper portion of the first memory channel structure 462.

FIG. 57 shows that the first memory channel structure 462 includes two portions, where the lower and upper portions, but the inventive concept is not limited thereto, and the first memory channel structure 462 may include three or more portions sequentially stacked. Each of the portions of the first memory channel structure 462 may have a width gradually decreasing from a top toward a bottom thereof, and an upper surface of a relatively lower portion may have a width greater than a width of a lower surface of an upper portion directly over the relatively lower portion.

Each of the first to sixth upper contact plugs 851, 853, 855, 857, 856 and 859 may have shape similar to that of the first memory channel structure 462. A portion of each of the first to sixth upper contact plugs 851, 853, 855, 857, 856 and 859 under the fifth insulating interlayer 660 may include a plurality of portions sequentially stacked in the first direction D1, and each of the portions may have a width gradually decreasing from a top toward a bottom thereof.

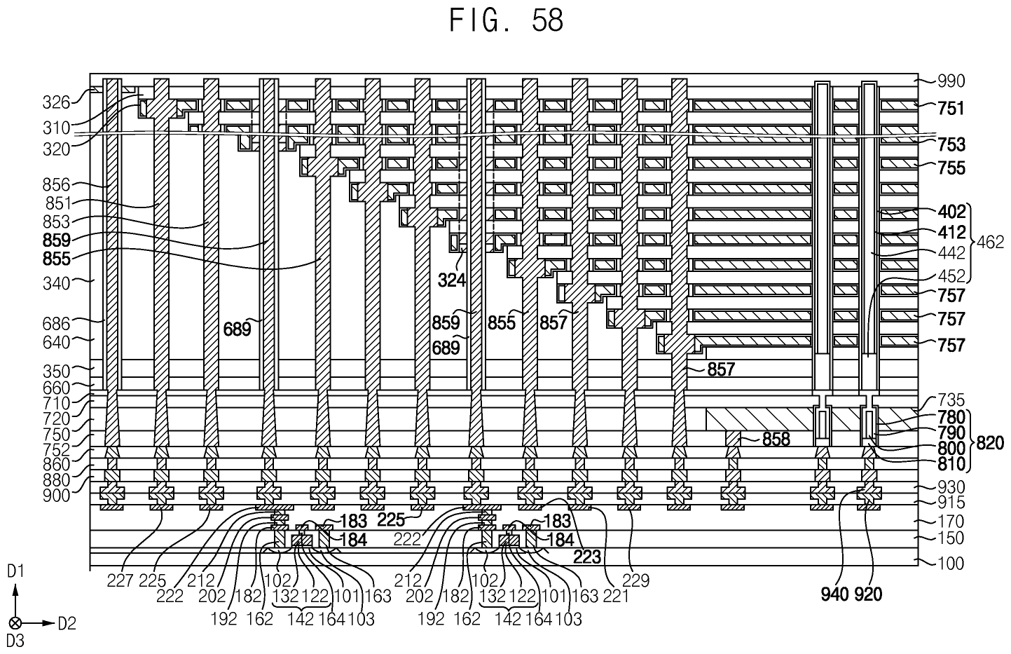

FIG. 58 is a cross-sectional view illustrating a semiconductor device in accordance with example embodiments, which may correspond to FIG. 6.

This semiconductor device may be substantially the same as or similar to the semiconductor device illustrated in FIGS. 1 to 7, except that the structures included in this semiconductor device are upside down, this semiconductor device further includes bonding patterns, and does not include the channel connection pattern 510, the support layer 300 and the support pattern 305.

Elements in the semiconductor device in FIGS. 1 to 7, which are referred to as “upper” and “lower”, may be referred to as “lower” and “upper” in FIG. 58.

In example embodiments, thirteenth and fourteenth insulating interlayers 910 and 930 may be sequentially stacked on the eighth to fourteenth lower wirings 222, 226, 221, 223, 225, 227 and 229 and the second insulating interlayer 170. Additionally, first bonding patterns 920 extending through the thirteenth insulating interlayer 910 and contacting the eighth to fourteenth lower wirings 222, 226, 221, 223, 225, 227 and 229 may be formed, and second bonding patterns 940 extending through the fourteenth insulating interlayer 930 and contacting the first bonding patterns 920 may be formed.

Each of the first and second bonding patterns 920 and 940 may include a metal, e.g., copper.

Upper portions of the first to sixth upper contact plugs 851, 853, 855, 857, 856 and 859, the first memory channel structure 462 and the support structure 688 may extend through a lower portion of an upper substrate 990, and an upper surface and an upper sidewall of the first channel 412 may not be covered by the second charge storage structure 402, but may contact the upper substrate 990. The upper substrate 990 may include a semiconductor material, e.g., silicon, germanium, silicon-germanium, etc., and may be doped with, e.g., n-type or p-type impurities.

While example embodiments have been particularly shown and described, it will be understood by one of ordinary skill in the art that variations in form and detail may be made therein without departing from the spirit and scope of the claims.

What is claimed is:

1. A semiconductor device comprising:
a gate electrode structure including first, second, third and fourth gate electrodes spaced apart from each other on a substrate in a first direction substantially perpendicular to an upper surface of the substrate, each of the first, second, third and fourth gate electrodes extending in a second direction substantially parallel to the upper surface of the substrate;
a first memory channel structure extending through the first, second and third gate electrodes on the substrate;
a second memory channel structure contacting an upper surface of the first memory channel structure and extending through the fourth gate electrode; and
a first contact plug including a lower portion and an upper portion, wherein the upper portion is on and contacting an upper surface of the lower portion, and wherein the lower portion extends partially through the gate electrode structure,
wherein the lower portion of the first contact plug extends through the first, second and third gate electrodes, and is electrically insulated from the first and second gate electrodes, and is electrically connected to the third gate electrode.

2. The semiconductor device of claim 1, wherein an upper surface of the lower portion of the first contact plug is substantially coplanar with an upper surface of the first memory channel structure.

3. The semiconductor device of claim 1, wherein an upper surface of the upper portion of the first contact plug is substantially coplanar with an upper surface of the second memory channel structure.

4. The semiconductor device of claim 1, wherein the first contact plug includes protrusion portions on portions of a sidewall of the first contact plug facing the first, second and third gate electrodes, respectively, the protrusion portion protruding in a horizontal direction substantially parallel to the upper surface of the substrate.

5. The semiconductor device of claim 4, wherein a width in the horizontal direction of an uppermost one of the protrusion portions of the first contact plug is greater than a width in the horizontal direction of other ones of the protrusion portions of the first contact plug.

6. The semiconductor device of claim 1, further comprising an insulation pattern between each of portions of a sidewall of the first contact plug facing the first and second gate electrodes, respectively, and a corresponding one of the first and second gate electrodes.

7. The semiconductor device of claim 1, wherein:
the second memory channel structure includes a second channel extending in the first direction,
the second channel includes a lower portion having a first width, a middle portion having a second width, and a third portion having a third width, and
each of the first and third widths is greater than the second width.

8. The semiconductor device of claim 1, wherein each of the first to third gate electrodes includes a metal, and the fourth gate electrode includes doped polysilicon.

9. The semiconductor device of claim 1, wherein the first gate electrode serves as a ground selection line (GSL), the second gate electrode serves as a word line, the third gate electrode is a gate induced drain leakage (GIDL) electrode, and the fourth gate electrode serves as a string selection line (SSL).

10. The semiconductor device of claim 1, further comprising second contact plugs, each of the second contact plugs including a lower portion and an upper portion on and contacting the lower portion, wherein the lower portion extends partially through the gate electrode structure,
wherein the lower portion of each of the second contact plugs has a width varying in the first direction, and the upper portion of each of the second contact plugs has a width gradually increasing from a bottom toward a top thereof, and
wherein the lower portion of each of the second contact plugs extends through the first and second gate electrodes, and is electrically insulated from the first gate electrode, and is electrically connected to the second gate electrode.

11. The semiconductor device of claim 10, wherein the second gate electrode is one of a plurality of second gate electrodes spaced apart from each other in the first direction,
wherein the lower portion of each of the second contact plugs extends through the plurality of second gate electrodes, and
wherein the lower portion of each of the second contact plugs is electrically connected to an uppermost one of the plurality of second gate electrodes, but is not electrically connected to other ones of the plurality of second gate electrodes.

12. A semiconductor device comprising:
a lower circuit pattern on a substrate;
an upper wiring over the lower circuit pattern;
a gate electrode structure including first, second, third and fourth gate electrodes spaced apart from each other over the upper wiring in a first direction substantially perpendicular to an upper surface of the substrate, each of the first, second, third and fourth gate electrodes extending in a second direction substantially parallel to the upper surface of the substrate;
a first memory channel structure extending through the first gate electrode;
a second memory channel structure contacting an upper surface of the first memory channel structure and extending through the second, third and fourth gate electrodes;
a first contact plug including an upper portion and a lower portion, wherein the lower portion is beneath and contacting a lower surface of the upper portion, and wherein the upper portion extends partially through the gate electrode structure; and
a second contact plug including an upper portion and a lower portion, wherein the lower portion is beneath and contacting a lower surface of the upper portion, and wherein the upper portion extends partially through the gate electrode structure,
wherein:
a length in the second direction of the fourth gate electrode is greater than a length in the second direction of the third gate electrode, the length in the second direction of the third gate electrode is greater than a length in the second direction of the second gate electrode, and the length in the second direction of the second gate electrode is greater than a length in the second direction of the first gate electrode,
the upper portion of the first contact plug extends through the second, third and fourth gate electrodes, and is not electrically connected to the third and fourth gate electrodes, but is electrically connected to the second gate electrode, and
the upper portion of the second contact plug extends through the third and fourth gate electrodes, and is not electrically connected to the fourth gate electrode, but is electrically connected to the third gate electrode.

13. The semiconductor device of claim 12, wherein a lower surface of the upper portion of each of the first and second contact plugs is substantially coplanar with a lower surface of the second memory channel structure.

14. The semiconductor device of claim 12, wherein a lower surface of the upper portion of each of the first and second contact plugs is substantially coplanar with a lower surface of the first memory channel structure.

15. The semiconductor device of claim 12, wherein the upper portion of each of the first and second contact plugs has a width gradually decreasing from a bottom toward a top thereof, and the lower portion of each of the first and second contact plugs has a width gradually decreasing from a bottom toward a top thereof.

16. The semiconductor device of claim 12, wherein the first gate electrode serves as an SSL, the second gate electrode is a GIDL electrode, the third gate electrode serves as a word line, and the fourth gate electrode serves as a GSL.

17. A semiconductor device comprising:
a lower circuit pattern on a substrate including first and second regions;
a common source plate (CSP) on the lower circuit pattern;
a gate electrode structure including first, second, third, fourth and fifth gate electrodes spaced apart from each other on the CSP in a first direction substantially perpendicular to an upper surface of the substrate, each of the first, second, third, fourth and fifth gate electrodes extending in a second direction substantially parallel to the upper surface of the substrate;
a first memory channel structure extending through the first to fourth gate electrodes on the CSP on the first region of the substrate;
a second memory channel structure contacting an upper surface of the first memory channel structure and extending through the fifth gate electrode;
a support structure on the CSP on the second region of the substrate, the support structure partially extending through the gate electrode structure;
a first contact plug including a lower portion and an upper portion, wherein the upper portion is on and contacting an upper surface of the lower portion, and wherein the lower portion extending partially through the gate electrode structure on the second region of the substrate; and
a second contact plug including a lower portion and an upper portion, wherein the upper portion is on and contacting an upper surface of the lower portion, and wherein the lower portion extends partially through the gate electrode structure on the second region of the substrate,
wherein:
the lower portion of each of the first and second contact plugs has a width varying in the first direction, and the upper portion of each of the first and second contact plugs has a width gradually increasing from a bottom toward a top thereof,
each of the first and second contact plugs contacts one of the first to fifth gate electrodes, and
upper surfaces of the first memory channel structure, the support structure and the lower portions of the first and second contact plugs are substantially coplanar with each other.

18. The semiconductor device of claim 17, wherein the support structure is one of a plurality of support structures spaced apart from each other in the second direction and in a third direction substantially parallel to the upper surface of the substrate and crossing the second direction, and
wherein each of the first and second contact plugs is disposed in an area surrounded by ones of the plurality of support structures in a plan view.

19. The semiconductor device of claim 17, wherein each of the first to fourth gate electrodes includes a metal, and the fifth gate electrode includes doped polysilicon.

20. The semiconductor device of claim 19, wherein the first gate electrode serves as a GSL, each of the second and fourth gate electrodes is a GIDL gate electrode, the third gate electrode serves as a word line, and the fifth gate electrode serves as an SSL.
